(19) United States
(12) Patent Application Publication
(10) Pub. No.: US 2025/0212630 A1
(43) Pub. Date: Jun. 26, 2025

(54) DISPLAY APPARATUS

(71) Applicant: Samsung Display Co., LTD., Yongin-si (KR)

(72) Inventors: Won Se LEE, Yongin-si (KR); Dong Hyeon JANG, Yongin-si (KR); Min Kyung PARK, Yongin-si (KR); Min Hee CHOI, Yongin-si (KR)

(21) Appl. No.: 18/890,196

(22) Filed: Sep. 19, 2024

(30) Foreign Application Priority Data
Dec. 21, 2023 (KR) 10-2023-0188046

(51) Int. Cl. H10K 59/131; H10K 59/88

(52) U.S. Cl. CPC H10K 59/131; H10K 59/88

(57) ABSTRACT

A display device includes a substrate; a circuit layer on the substrate; and an element layer on the circuit layer, wherein the substrate includes a main area including a display area where emission areas are arranged and a non-display area around the display area, and a hole area, the main area being around the hole area, the element layer comprises light emitting elements respectively in the emission areas, and the circuit layer includes: emission pixel drivers arranged side by side along a first direction and a second direction and electrically connected to the light emitting elements, respectively; data lines extending in the second direction and configured to supply data signals to the emission pixel drivers; bridge lines extending in the first direction; and additional lines extending in the second direction and neighboring the data lines, the bridge lines include first dummy bridge lines facing the hole area.

### CROSS-REFERENCE TO RELATED APPLICATION

The present application claims priority to and the benefit of Korean Patent Application No. 10-2023-0188046, filed on Dec. 21, 2023, in the Korean Intellectual Property Office, the entire disclosure of which is incorporated by reference herein.

### BACKGROUND

### 1. Field

The present disclosure relates to a display device.

### 2. Description of the Related Art

As the information society develops, the demand for display devices for displaying images has increased and diversified. For example, display devices have been applied to various electronic devices such as smartphones, digital cameras, laptop computers, navigation devices, and/or smart televisions.

The display devices may be flat panel display devices such as liquid crystal display devices, field emission display devices, and/or light emitting display devices. Here, the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements each including a light emitting layer made of an organic light emitting material. As such, the organic light emitting display device implements image display using self-light emitting elements, and accordingly, may have relatively excellent performance in terms of power consumption, response speed, luminous efficiency, luminance, wide viewing angle, and/or the like, compared to other display devices.

One surface of the display device may be a display surface including a display area where an image is displayed. Emission areas emitting light of each luminance and color may be arranged in the display area.

### SUMMARY

In one or more embodiments, a display device includes: a substrate; a circuit layer on the substrate; and an element layer on the circuit layer, wherein the substrate includes a main area including a display area where emission areas are arranged and a non-display area around the display area, and a hole area, the main area being around the hole area, the element layer includes light emitting elements respectively in the emission areas, and the circuit layer includes: emission pixel drivers arranged side by side along a first direction and a second direction and electrically connected to the light emitting elements, respectively; data lines extending in the second direction and configured to supply data signals to the emission pixel drivers; bridge lines extending in the first direction; and additional lines extending in the second direction and neighboring the data lines, the bridge lines include one or more first dummy bridge lines facing the hole area on one side in the second direction and one or more second dummy bridge lines facing the hole area on an other side in the second direction, and the additional lines include one or more first dummy additional lines facing the hole area on the one side in the first direction and electrically connected to the one or more first dummy bridge lines and the one or more second dummy bridge lines.

In one or more embodiments, the additional lines further include one or more second dummy additional lines facing the hole area on the other side in the first direction and electrically connected to the one or more first dummy bridge lines and the one or more second dummy bridge lines.

In one or more embodiments, a light transmitting hole penetrating through the circuit layer and the element layer is in at least a portion of a middle of the hole area, wherein the substrate further includes a sub-area protruding from one side of the main area, wherein the main area further includes a hole bypass area around the hole area, wherein the hole bypass area includes a first hole bypass partitioned area and a second hole bypass partitioned area that neighbor each other on the basis of a first hole central point extension line crossing a central point of the hole area and extending in the first direction, and a third hole bypass partitioned area and a fourth hole bypass partitioned area that respectively neighbor the first hole bypass partitioned area and the second hole bypass partitioned area on the basis of a second hole central point extension line crossing the central point of the hole area and extending in the second direction, wherein an edge of the display area includes a first side that extends in the first direction and faces the sub-area in the second direction and a second side that extends in the first direction, opposes the first side in the second direction, and is spaced farther from the sub-area than the first side is, wherein the data lines include hole crossing data lines crossing the hole area, wherein each of the hole crossing data lines includes a first divided line portion between the first side and the hole area and a second divided line portion between the hole area and the second side, wherein the hole crossing data lines include a first hole crossing data line facing the second hole central point extension line on one side in the first direction, wherein the bridge lines further include a first hole bypass bridge line in the first hole bypass partitioned area and electrically connected to the first divided line portion of the first hole crossing data line and a second hole bypass bridge line in the second hole bypass partitioned area and electrically connected to the second divided line portion of the first hole crossing data line, wherein the additional lines further include a first hole bypass additional line in the first hole bypass partitioned area and the second hole bypass partitioned area and electrically connected between the first hole bypass bridge line and the second hole bypass bridge line, and wherein the one or more first dummy additional lines are between the first hole bypass additional line and the hole area in the first direction.

In one or more embodiments, the hole crossing data lines further include a second hole crossing data line facing the second hole central point extension line on the other side in the first direction, wherein the bridge lines further include a third hole bypass bridge line in the third hole bypass partitioned area and electrically connected to the first divided line portion of the second hole crossing data line and a fourth hole bypass bridge line in the fourth hole bypass partitioned area and electrically connected to the second divided line portion of the second hole crossing data line, wherein the additional lines further include a second hole bypass additional line in the third hole bypass partitioned area and the fourth hole bypass partitioned area and electrically connected between the third hole bypass bridge line and the fourth hole bypass bridge line, and wherein the one or more second dummy additional lines are between the hole area and the second hole bypass additional line in the first direction.

In one or more embodiments, the additional lines further include: one or more third dummy additional lines between the first side and the hole area in the second direction and between the one or more first dummy additional lines and the one or more second dummy additional lines in the first direction; and one or more fourth dummy additional lines between the hole area and the second side in the second direction and between the one or more first dummy additional lines and the one or more second dummy additional lines in the first direction, wherein the one or more third dummy additional lines are electrically connected to the one or more first dummy additional lines and the one or more second dummy additional lines through the one or more first dummy bridge lines, and wherein the one or more fourth dummy additional lines are electrically connected to the one or more first dummy additional lines and the one or more second dummy additional lines through the one or more second dummy bridge lines.

In one or more embodiments, the bridge lines further include: two or more third dummy bridge lines between the first hole bypass bridge line and the third hole bypass bridge line and between the second hole bypass bridge line and the fourth hole bypass bridge line; and one or more fourth dummy bridge lines between the one or more first dummy bridge lines and the one or more second dummy bridge lines in the second direction and crossing the hole area, wherein the two or more third dummy bridge lines are electrically connected to the one or more first dummy bridge lines or the one or more second dummy bridge lines through the one or more third dummy additional lines and the one or more fourth dummy additional lines, and wherein the one or more fourth dummy bridge lines are electrically connected to the one or more first dummy additional lines or the one or more second dummy additional lines.

In one or more embodiments, a portion of the second hole bypass partitioned area overlaps the display area, and an other portion of the second hole bypass partitioned area overlaps the non-display area, and wherein the circuit layer further includes a first bridge auxiliary line in the non-display area, extending in the first direction, and electrically connected between the first hole bypass additional line and the second divided line portion of the first hole crossing data line.

In one or more embodiments, a portion of the fourth hole bypass partitioned area overlaps the display area, and an other portion of the fourth hole bypass partitioned area overlaps the non-display area, and the circuit layer further includes a second bridge auxiliary line in the non-display area, extending in the first direction, and electrically connected between the second hole bypass additional line and the second divided line portion of the second hole crossing data line.

In one or more embodiments, the circuit layer further includes a first power supply line and a second power supply line in the non-display area and respectively configured to supply first power and second power to drive the light emitting elements, wherein a portion of the second power supply line extends in parallel with the second side, and wherein the one or more first dummy additional lines and the one or more second dummy additional lines are electrically connected to the second power supply line.

In one or more embodiments, the circuit layer further includes a first power supply line and a second power supply line in the non-display area and respectively configured to supply first power and second power to drive the light emitting elements, wherein a portion of the first power supply line extends in parallel with the second side, and wherein the one or more first dummy additional lines and the one or more second dummy additional lines are electrically connected to the first power supply line.

In one or more embodiments, the circuit layer further includes: a first power supply line and a second power supply line in the non-display area and respectively configured to supply first power and second power to drive the light emitting elements; and a constant voltage supply line configured to supply a constant voltage having a different voltage level from the first power and the second power in the non-display area, wherein a portion of the constant voltage supply line extends in parallel with the second side, and wherein the one or more first dummy additional lines and the one or more second dummy additional lines are electrically connected to the constant voltage supply line.

In one or more embodiments, one of the light emitting elements is electrically connected between one of the emission pixel drivers and the second power, wherein the emission pixel driver includes: a first transistor configured to generate a driving current for driving the light emitting element; a second transistor electrically connected between one of the data lines and a first electrode of the first transistor; a third transistor electrically connected between a gate electrode of the first transistor and a second electrode of the first transistor; a fourth transistor electrically connected between a first initialization voltage line configured to supply a first initialization voltage and the gate electrode of the first transistor; a fifth transistor electrically connected between a first power line configured to supply the first power and the first electrode of the first transistor; a sixth transistor electrically connected between the second electrode of the first transistor and the light emitting element; a seventh transistor electrically connected between a second initialization voltage line configured to supply a second initialization voltage and the light emitting element; and an eighth transistor electrically connected between a bias voltage line configured to supply a bias voltage and the first electrode of the first transistor, and wherein the constant voltage supply line is configured to supply one of the first initialization voltage, the second initialization voltage, and the bias voltage.

In one or more embodiments, the data lines further include a first data line and a second data line that is spaced farther from the sub-area than the first data line is, wherein the bridge lines further include a data bypass bridge line electrically connected to the second data line, and wherein the additional lines further include a data bypass additional line neighboring the first data line and electrically connected to the data bypass bridge line.

In one or more embodiments, the circuit layer further includes data supply lines electrically connected between a display driving circuit in the sub-area and the data lines, a first data supply line configured to supply a data signal of the first data line from among the data supply lines extends to the first data line and is directly electrically connected to the first data line, and a second data supply line configured to supply a data signal of the second data line from among the data supply lines extends to the data bypass additional line and is electrically connected to the second data line through the data bypass additional line and the data bypass bridge line.

In one or more embodiments, the edge of the display area further includes a third side and a fourth side that extend in the second direction and oppose each other in the first direction, wherein the data bypass bridge line is spaced from the third side and the fourth side, wherein the bridge lines further include power auxiliary bridge lines between one end of the data bypass bridge line and the third side and between other end of the data bypass bridge line and the fourth side, and wherein the additional lines further include a power auxiliary additional line between one end of the data bypass additional line and the second side.

In one or more embodiments, a display device includes: a substrate; a circuit layer on the substrate; and an element layer on the circuit layer, wherein the substrate includes a main area including a display area where emission areas are arranged and a non-display area around the display area, a hole area, and a sub-area protruding from one side of the main area, the main area being around the hole area, the element layer includes light emitting elements respectively located in the emission areas, the circuit layer includes: emission pixel drivers arranged side by side along a first direction and a second direction and electrically connected to the light emitting elements, respectively; data lines extending in the second direction and configured to supply data signals to the emission pixel drivers; bridge lines extending in the first direction; and additional lines extending in the second direction and neighboring the data lines, the main area further includes a hole bypass area around the hole area, the data lines include hole crossing data lines crossing the hole area, each of the hole crossing data lines includes a first divided line portion on one side in the second direction and a second divided line portion on the other side in the second direction, on the basis of a first hole central point extension line crossing a central point of the hole area and extending in the first direction, the hole crossing data lines include a first hole crossing data line on one side in the first direction and a second hole crossing data line on the other side in the first direction, on the basis of a second hole central point extension line crossing the central point of the hole area and extending in the second direction, the bridge lines include: a first hole bypass bridge line electrically connected to the first divided line portion of a first hole bridge data line; a second hole bypass bridge line electrically connected to the second divided line portion of the first hole bridge data line; a third hole bypass bridge line electrically connected to the first divided line portion of a second hole bridge data line; a fourth hole bypass bridge line electrically connected to the second divided line portion of the second hole bridge data line; one or more first dummy bridge lines facing the hole area on one side in the second direction; and one or more second dummy bridge lines facing the hole area on the other side in the second direction, the additional lines include: a first hole bypass additional line electrically connected between the first hole bypass bridge line and the second hole bypass bridge line; a second hole bypass additional line electrically connected between the third hole bypass bridge line and the fourth hole bypass bridge line; one or more first dummy additional lines facing the hole area on one side in the first direction and electrically connected to the first dummy bridge line and the second dummy bridge line; and one or more second dummy additional lines facing the hole area on the other side in the first direction and electrically connected to the first dummy bridge line and the second dummy bridge line, and the one or more first dummy bridge lines, the one or more second dummy bridge lines, the one or more first dummy additional lines, and the one or more second dummy additional lines are electrically connected to each other.

In one or more embodiments, the bridge lines further include: two or more third dummy bridge lines between the first hole bypass bridge line and the third hole bypass bridge line and between the second hole bypass bridge line and the fourth hole bypass bridge line; and one or more fourth dummy bridge lines between the one or more first dummy bridge lines and the one or more second dummy bridge lines in the second direction and crossing the hole area, wherein the additional lines further include: one or more third dummy additional lines adjacent to one side of the hole area in the second direction and between the one or more first dummy additional lines and the one or more second dummy additional lines in the first direction; and one or more fourth dummy additional lines adjacent to the other side of the hole area in the second direction and between the one or more first dummy additional lines and the one or more second dummy additional lines in the first direction, and the two or more third dummy bridge lines, the one or more fourth dummy bridge lines, the one or more third dummy additional lines, and the one or more fourth dummy additional lines are electrically connected to the one or more first dummy bridge lines, the one or more second dummy bridge lines, the one or more first dummy additional lines, and the one or more second dummy additional lines.

In one or more embodiments, the circuit layer further includes a first power supply line and a second power supply line in the non-display area and respectively configured to supply first power and second power to drive the light emitting elements, and wherein the one or more first dummy additional lines and the one or more second dummy additional lines are electrically connected to one of the first power supply line and the second power supply line.

In one or more embodiments, the circuit layer further includes: a first initialization voltage line configured to supply a first initialization voltage to the emission pixel drivers; a second initialization voltage line configured to supply a second initialization voltage to the emission pixel drivers; a bias voltage line transferring a bias voltage to the emission pixel drivers; and a constant voltage supply line in the non-display area, wherein the constant voltage supply line is configured to supply one of the first initialization voltage, the second initialization voltage, and the bias voltage, and wherein the one or more first dummy additional lines and the one or more second dummy additional lines are electrically connected to the constant voltage supply line.

In one or more embodiments, a portion of the hole bypass area overlaps the display area, and an other portion of the hole bypass area overlaps the non-display area, and wherein the circuit layer further includes: a first bridge auxiliary line in the non-display area, extending in the first direction, and electrically connected between the first hole bypass additional line and the second divided line portion of the first hole crossing data line; and a second bridge auxiliary line in the non-display area, extending in the first direction, and electrically connected between the second hole bypass additional line and the second divided line portion of the second hole crossing data line.

According to one or more embodiments, the one or more first dummy bridge lines, the one or more second dummy bridge lines, the one or more first dummy additional lines, and the one or more second dummy additional lines may be electrically connected to each other.

In this way, the one or more first dummy bridge lines and the one or more second dummy bridge lines that are adjacent to the hole area in the first direction and the one or more first dummy additional lines and the one or more second dummy lines that are adjacent to the hole area in the second direction may be maintained at the same potential, and thus, a deviation between luminance characteristics of emission areas adjacent to the hole area may be reduced.

Accordingly, deterioration of image quality caused by the one or more first dummy bridge lines, the one or more second dummy bridge lines, the one or more first dummy additional lines, and the one or more second dummy additional lines may be alleviated.

In addition, according to one or more embodiments, the additional lines may further include one or more third dummy additional lines and one or more fourth dummy additional lines disposed between the one or more first dummy additional lines and the one or more second dummy additional lines in the first direction. The one or more third dummy additional lines may be disposed adjacent to one side of the hole area in the second direction. The one or more fourth dummy additional lines may be disposed adjacent to the other side of the hole area in the second direction.

In addition, the bridge lines may further include two or more third dummy bridge lines disposed between the first hole bypass bridge line and the third hole bypass bridge line and between the second hole bypass bridge line and the fourth hole bypass bridge line, and one or more fourth dummy bridge lines disposed between the one or more first dummy bridge lines and the one or more second dummy bridge lines in the second direction and crossing the hole area.

According to one or more embodiments, the two or more third dummy bridge lines, the one or more fourth dummy bridge lines, the one or more third dummy additional lines, and the one or more fourth dummy additional lines may be electrically connected to the one or more first dummy bridge lines, the one or more second dummy bridge lines, the one or more first dummy additional lines, and the one or more second dummy additional lines.

In other words, some of the bridge lines disposed around the hole area and some of the additional lines disposed around the hole area may be bypass lines of the hole crossing data lines for bypassing the hole area, and the others of the bridge lines disposed around the hole area and the other of the additional lines disposed around the hole area may be dummy lines maintained at the same potential.

In this way, the dummy lines disposed around the hole area are maintained at the same potential, such that a deviation of electrical influences of the dummy lines may be eliminated, and thus, degradation of image quality around the hole area may be further alleviated.

Accordingly, even though the display device according to one or more embodiments includes a through hole disposed in the hole area, image quality of some areas of the display area adjacent to the hole area may become similar to image quality of the other areas, and thus, display quality of the display device may be improved.

The effects, aspects, and features of the present disclosure are not limited to the aforementioned effects, aspects, and features, and various other effects, aspects, and features are included in the present disclosure.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view illustrating a display device according to one or more embodiments;

FIG. 2 is a plan view illustrating the display device of FIG. 1;

FIG. 3 is a cross-sectional view taken along the line A-A′ of FIG. 2;

FIG. 4 is a layout diagram illustrating a portion B of FIG. 2;

FIG. 5 is an equivalent circuit diagram illustrating an emission pixel driver of FIG. 4;

FIG. 6 is a cross-sectional view illustrating a first transistor, a second transistor, a fourth transistor, a sixth transistor, and a light emitting element of FIG. 5;

FIG. 7 is a plan view illustrating a substrate of FIG. 3;

FIG. 8 is a layout diagram illustrating a portion C of FIG. 7;

FIG. 9 is a cross-sectional view taken along the line E-E′ of FIG. 8;

FIG. 10 is a layout diagram illustrating a portion D of FIG. 7 according to one or more embodiments;

FIG. 11 is a layout diagram illustrating the portion D of FIG. 7 according to one or more embodiments;

FIG. 12 is a cross-sectional view taken along the line F-F′ of FIG. 11;

FIG. 13 is a layout diagram illustrating the portion D of FIG. 7 according to one or more embodiments;

FIG. 14 is a layout diagram illustrating the portion D of FIG. 7 according to one or more embodiments;

FIG. 15 is a layout diagram illustrating the portion D of FIG. 7 according to one or more embodiments; and

FIG. 16 is a layout diagram illustrating the portion D of FIG. 7 according to one or more embodiments.

### DETAILED DESCRIPTION

Aspects and features of embodiments of the present disclosure and methods of accomplishing the same may be understood more readily by reference to the following detailed description of embodiments and the accompanying drawings. The present disclosure may, however, be embodied in many different forms and should not be construed as being limited to embodiments set forth herein. Rather, these embodiments are provided so that the present disclosure will be thorough and complete and will fully convey the concept of the present disclosure to those skilled in the art, and the present disclosure will be defined by the appended claims and their equivalents.

It will be understood that when an element or layer is referred to as being “on” another element or layer, the element or layer can be directly on another element or layer or intervening elements or layers. Like reference numerals refer to like elements throughout the present disclosure. Shapes, sizes, ratios, angles, numbers, etc. disclosed in the drawings for describing embodiments are merely an example, and the present disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the present disclosure.

Features of various embodiments of the present disclosure may be partially or entirely coupled to or combined with each other, and may be inter-operated and driven in technically various ways. Embodiments of the present disclosure may be implemented independently from each other, or may be implemented together in a co-dependent relationship.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, specific embodiments will be described with reference to the accompanying drawings.

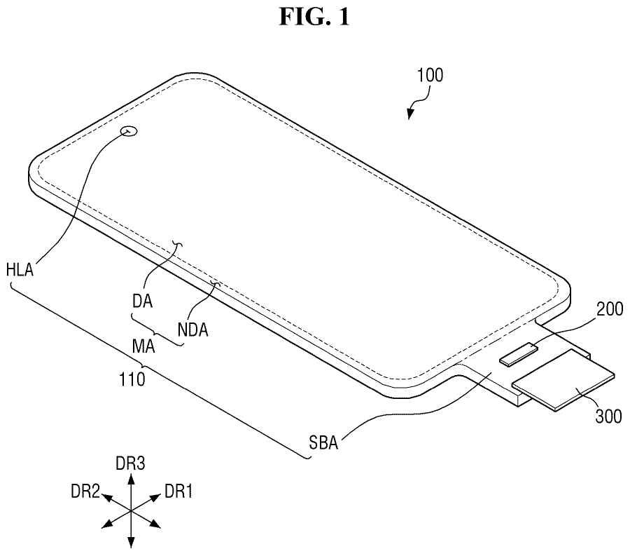

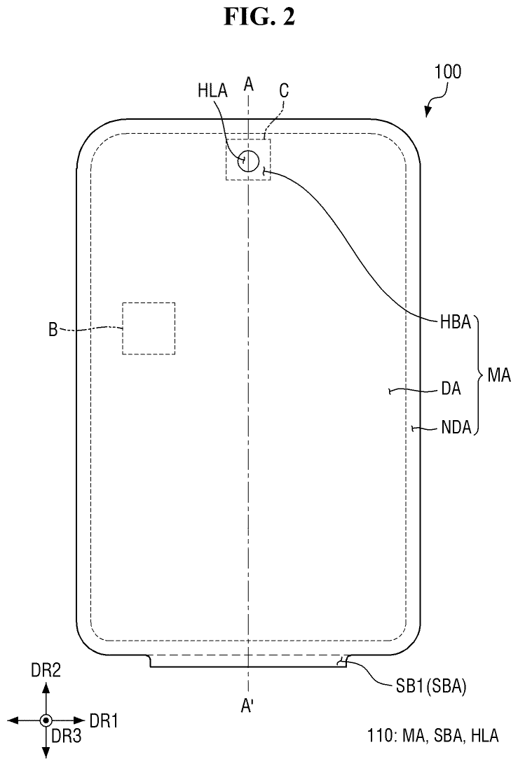

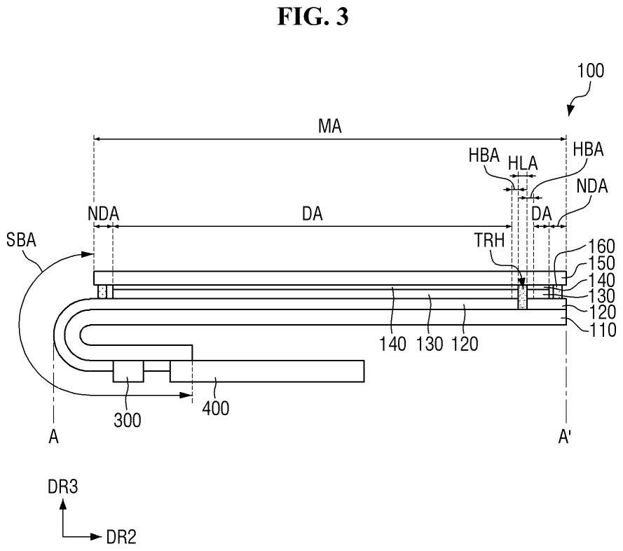

FIG. 1 is a perspective view illustrating a display device according to one or more embodiments. FIG. 2 is a plan view illustrating the display device of FIG. 1. FIG. 3 is a cross-sectional view taken along the line A-A′ of FIG. 2.

Referring to FIGS. 1 and 2, a display device 100 is a device that displays a moving image and/or a still image, and may be used as a display screen of various products such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and/or ultra mobile PCs (UMPCs).

The display device 100 may be a light emitting display device such as an organic light emitting display device using organic light emitting diodes (OLEDs), a quantum dot light emitting display device including quantum dot light emitting layers, an inorganic light emitting display device including inorganic semiconductors, and a micro light emitting display device using micro or nano light emitting diodes (micro LEDs or nano LEDs). Hereinafter, it will be mainly described that the display device 100 is an organic light emitting display device. However, the present disclosure is not limited thereto, and may be applied to a display device including an organic insulating material, an organic light emitting material, and/or a metal material.

The display device 100 may be formed to be flat, but is not limited thereto. For example, the display device 100 may include curved surface portions formed at left and right ends thereof and having a constant curvature or a variable curvature. In addition, the display device 100 may be flexibly formed to be curved, bent, folded, and/or rolled.

As illustrated in FIGS. 1-3, the display device 100 includes a substrate 110.

The substrate 110 may include a main area MA corresponding to a display surface of the display device 100 and a sub-area SBA protruding from one side of the main area MA.

As illustrated in FIG. 2, the main area MA may include a display area DA disposed at most of the center thereof and a non-display area NDA disposed around the display area DA.

The display area DA may be formed in a rectangular shape, in a plan view, having short sides extending in a first direction DR1 and long sides extending in a second direction DR2 crossing the first direction DR1. A corner where the short side in the first direction DR1 and the long side in the second direction DR2 meet may be rounded with a suitable curvature (e.g., a predetermined curvature) or right-angled. A shape of the display area DA in a plan view is not limited to the rectangular shape, and may be other polygonal shapes, a circular shape, and/or an elliptical shape.

The non-display area NDA may be disposed at an edge or a periphery of the main area MA so as to be around (e.g., to surround) the display area DA.

The sub-area SBA may be an area protruding from the non-display area NDA of the main area MA to one side in the second direction DR2.

FIGS. 2 and 3 illustrate the display device 100 in a state in which a portion of the sub-area SBA is bent.

As illustrated in FIGS. 2 and 3, a portion of the sub-area SBA is transformed into a bent shape, such that another portion of the sub-area SBA may be disposed on a rear surface of the display device 100. In one or more embodiments, the substrate 110 of the display device 100 may include a hole area HLA, and the main area MA of the substrate 110 may include a hole bypass area HBA disposed around the hole area HLA. In one or more embodiments, a display driving circuit 200 may be disposed in the sub-area SBA and a circuit board 300 may be disposed at an edge of one side of the sub-area SBA.

In one or more embodiments, as shown with respect to FIGS. 1-7, the sub-area SBA may include a bending area BA transformed into a bent shape, a first sub-area SB1 disposed between one side of the bending area BA and the main area MA, and a second sub-area SB2 connected to the other side of the bending area BA.

Referring to FIG. 3, the display device 100 according to one or more embodiments includes a substrate 110, a circuit layer 120 disposed on the substrate 110, and an element layer 130 disposed on the circuit layer 120.

The display device 100 according to one or more embodiments may further include a sealing layer 140 disposed on the element layer 130 and a touch sensor layer 150 disposed on the sealing layer 140.

In addition, the display device 100 according to one or more embodiments may further include a polarizing layer 160 disposed on the touch sensor layer 150 in order to reduce external light reflection.

The substrate 110 may be made of an insulating material such as a polymer resin. For example, the substrate 110 may be made of polyimide. The substrate 110 may be a flexible substrate that may be bent, folded, and/or rolled.

Alternatively, the substrate 110 may be made of an insulating material such as glass.

The substrate 110 may include a main area MA and a sub-area SBA. The main area MA may include a display area DA and a non-display area NDA.

The circuit layer 120 may include insulating layers, conductive layers, and one or more semiconductor layers. One or more insulating layers may be interposed between the conductive layers and one or more semiconductor layers. The circuit layer 120 may include transistors provided as one or more semiconductor layers and one or more conductive layers and signal lines each provided as at least one of the conductive layers.

The element layer 130 may include light emitting elements.

The sealing layer 140 may cover the circuit layer 120 and the element layer 130, and may block permeation of oxygen and/or moisture into the element layer 130.

The touch sensor layer 150 may include touch electrodes and touch lines connected to the touch electrodes.

In one or more embodiments, a light transmitting hole TRH penetrating through the circuit layer 120, the element layer 130, and the sealing layer 140 is disposed in at least a portion of the middle of the hole area HLA.

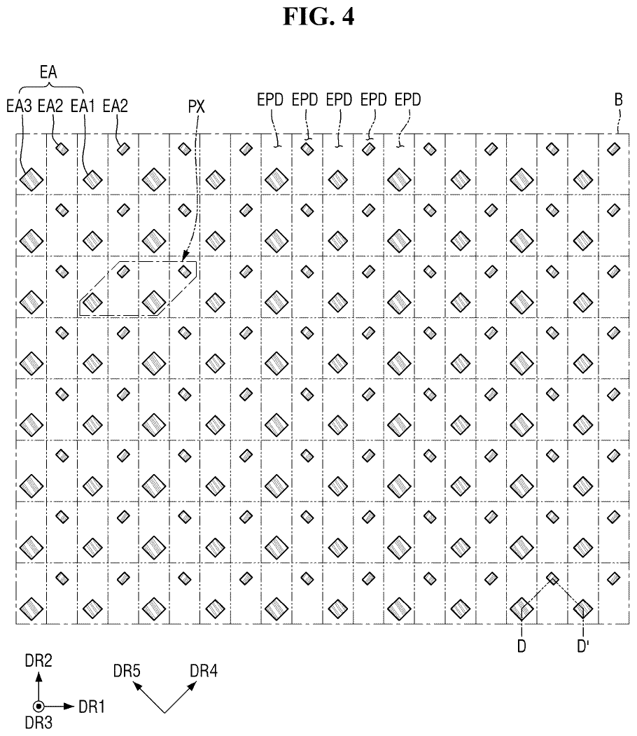

FIG. 4 is a layout diagram illustrating a portion B of FIG. 2.

Referring to FIG. 4, the display area DA of the display device 100 according to one or more embodiments may include emission areas EA (e.g., EA1, EA2, EA3). In addition, the display area DA may further include a non-emission area disposed in a spaced portion between the emission areas EA.

The element layer 130 (see FIG. 3) may include light emitting elements LE respectively disposed in the emission areas EA.

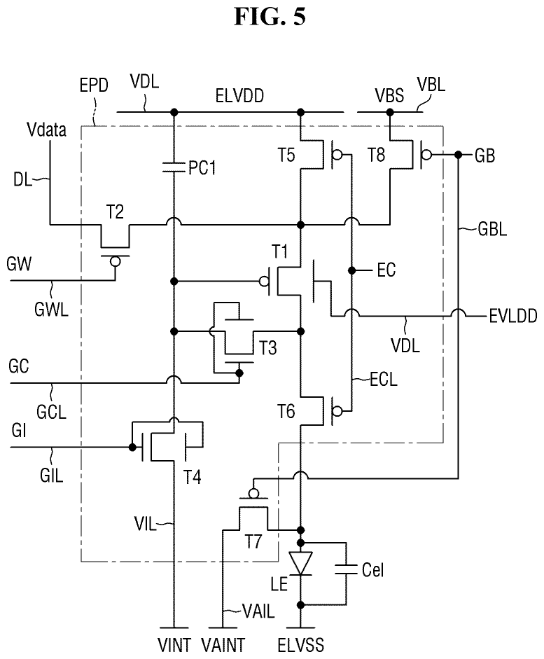

The circuit layer 120 (see FIG. 3) may include emission pixel drivers EPD arranged side by side along the first direction DR1 and the second direction DR2 in the main area MA. The emission pixel drivers EPD may be electrically connected to the light emitting elements LE (see FIG. 5) of the element layer 130, respectively.

The emission areas EA may have a rhombic shape in a plan view or a rectangular shape in a plan view. However, this is only an example, and a shape of the emission areas EA in a plan view according to one or more embodiments is not limited to that illustrated in FIG. 5. That is, the emission areas EA may have a polygonal shape such as a quadrangular shape, a pentagonal shape, or a hexagonal shape in a plan view or have a circular shape or an elliptical shape, in a plan view, including a curved edge.

The emission areas EA may include first emission areas EA1 emitting light of a first color in a suitable wavelength band (e.g., a predetermined wavelength band), second emission areas EA2 emitting light of a second color in a wavelength band lower than that of the first color, and third emission areas EA3 emitting light of a third color in a wavelength band lower than that of the second color.

As an example, the first color may be red corresponding to a wavelength band of approximately 600 nm to 750 nm. The second color may be green corresponding to a wavelength band of approximately 480 nm to 560 nm. The third color may be blue corresponding to a wavelength band of approximately 370 nm to 460 nm.

The first emission areas EA1 and the third emission areas EA3 may be alternately disposed along at least one of the first direction DR1 or the second direction DR2.

The second emission areas EA2 may be arranged side by side in at least one of the first direction DR1 or the second direction DR2.

In addition, the second emission areas EA2 may neighbor the first emission areas EA1 and the third emission areas EA3 in diagonal directions DR4 and DR5 crossing the first direction DR1 and the second direction DR2.

Pixels PX displaying each luminance and color may be provided by the first emission areas EA1, the second emission areas EA2, and the third emission areas EA3 adjacent to each other from among such emission areas EA.

In other words, the pixels PX may be basic units displaying various colors including white at a suitable luminance (e.g., a predetermined luminance).

Each of the pixels PX may include at least one first emission area EA1, at least one second emission area EA2, and at least one third emission area EA3 adjacent to each other. Accordingly, each of the pixels PX may display various colors through mixing of light emitted from the first emission area EA1, the second emission area EA2, and the third emission area EA3 adjacent to each other.

FIG. 5 is an equivalent circuit diagram illustrating an emission pixel driver of FIG. 4.

Referring to FIG. 5, one light emitting element LE of the light emitting elements LE of the element layer 130 may be electrically connected between one emission pixel driver EPD of the emission pixel drivers EPD of the circuit layer 120 and a second power ELVSS.

That is, an anode electrode of the light emitting element LE may be electrically connected to the emission pixel driver EPD, and the second power ELVSS having a lower voltage level than a first power ELVDD may be applied to a cathode electrode of the light emitting element LE.

A capacitor Cel connected to the light emitting element LE, in parallel between the anode electrode and the cathode electrode, indicates parasitic capacitance between the anode electrode and the cathode electrode.

The circuit layer 120 may further include a first power line VDL transferring the first power ELVDD, a first initialization voltage line VIL transferring a first initialization voltage VINT, a second initialization voltage line VAIL transferring a second initialization voltage VAINT, and a bias voltage line VBL transferring a bias voltage VBS.

The circuit layer 120 may further include a data line DL transferring a data signal Vdata, a scan write line GWL transferring a scan write signal GW, a scan initialization line GIL transferring a scan initialization signal GI, an emission control line ECL transferring an emission control signal EC, a gate control line GCL transferring a gate control signal GC, and a bias control line GBL transferring a bias control signal GB.

One emission pixel driver EPD of the circuit layer 120 may include a first transistor T1 generating a driving current for driving the light emitting element LE, two or more transistors T2 to T8 electrically connected to the first transistor T1, and at least one capacitor PC1.

The first transistor T1 may generate the driving current for driving the light emitting element LE.

A first electrode (e.g., a source electrode) of the first transistor T1 may be electrically connected to the first power line VDL through a fifth transistor T5.

A second electrode (e.g., a drain electrode) of the first transistor T1 may be electrically connected to the anode electrode of the light emitting element LE through a sixth transistor T6.

The first electrode of the first transistor T1 may be electrically connected to a data line DL through a second transistor T2.

A gate electrode of the first transistor T1 may be electrically connected to the first power line VDL through a first capacitor PC1.

That is, the first capacitor PC1 may be electrically connected between the gate electrode of the first transistor T1 and the first power line VDL.

Accordingly, a potential of the gate electrode of the first transistor T1 may be maintained as a voltage charged in the first capacitor PC1.

In addition, when a data signal Vdata of the data line DL is transferred to the first electrode of the first transistor T1 through the turned-on second transistor T2, a voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1, that is, a gate-source voltage difference, is greater than or equal to a threshold voltage, the first transistor T1 is turned on, such that a drain-source current of the first transistor T1 corresponding to the data signal Vdata may be generated.

Subsequently, when the fifth transistor T5 and the sixth transistor T6 are turned on, the first transistor T1 may be connected to the light emitting element LE in series between the first power ELVDD and the second power ELVSS. Accordingly, the drain-source current of the first transistor T1 corresponding to the data signal Vdata may be supplied as the driving current of the light emitting element LE.

Accordingly, the light emitting element LE may emit light of luminance corresponding to the data signal Vdata.

The second transistor T2 may be electrically connected between the first electrode of the first transistor T1 and the data line DL. The second transistor T2 may be turned on by the scan write signal GW of the scan write line GWL.

A third transistor T3 may be electrically connected between the gate electrode of the first transistor T1 and the second electrode of the first transistor T1. The third transistor T3 may be turned on by the gate control signal GC of the gate control line GCL.

A fourth transistor T4 may be connected between the gate electrode of the first transistor T1 and the first initialization voltage line VIL. The fourth transistor T4 may be turned on by the scan initialization signal GI of the scan initialization line GIL.

The third transistor T3 and the fourth transistor T4 may be provided as N-type metal oxide semiconductor field effect transistors (N-type MOSFETs).

The fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL.

A seventh transistor T7 may be electrically connected between the anode electrode of the light emitting element LE and the second initialization voltage line VAIL. The seventh transistor T7 may be turned on by the bias control signal GB of the bias control line GBL.

An eighth transistor T8 may be electrically connected between the first electrode of the first transistor T1 and the bias voltage line VBL.

The eighth transistor T8 may be turned on by the bias control signal GB of the bias control line GBL.

According to one or more embodiments, the third transistor T3 and the fourth transistor T4 of the first to eighth transistors T1 to T8 may be provided as the N-type MOSFETs, and the transistors T1, T2, and T5 to T8 other than the third transistor T3 and the fourth transistor T4 may be provided as P-type MOSFETs.

Accordingly, each of the third transistor T3 and the fourth transistor T4 may include a channel portion, a source portion, and a drain portion disposed at a different semiconductor layer from the other transistors T1, T2, and T5 to T8.

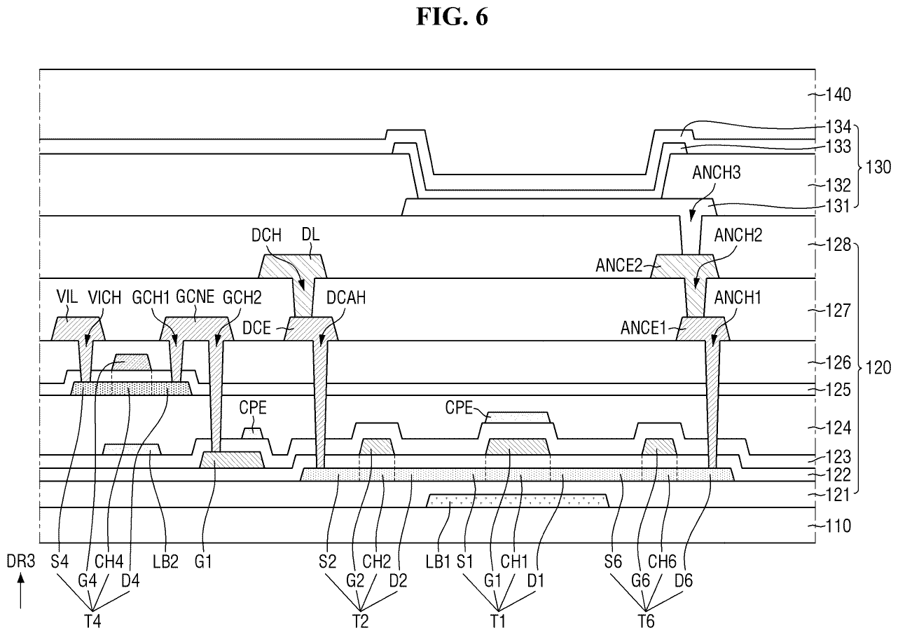

FIG. 6 is a cross-sectional view illustrating a first transistor, a second transistor, a fourth transistor, a sixth transistor, and a light emitting element of FIG. 5.

Referring to FIG. 6, the circuit layer 120 of the display device 100 according to one or more embodiments may include a buffer layer 121 covering a first light blocking layer LB1 disposed on the substrate 110, a first semiconductor layer CH1, S1, D1, CH2, S2, D2, CH6, S6, and D6 disposed on the buffer layer 121, a first gate insulating layer 122 covering the first semiconductor layer CH1, S1, D1, CH2, S2, D2, CH6, S6, and D6 and the buffer layer 121, a first gate conductive layer G1, G2, and G6 disposed on the first gate insulating layer 122, a second gate insulating layer 123 covering the first gate conductive layer G1, G2, and G6 and the first gate insulating layer 122, a second gate conductive layer CPE and LB2 disposed on the second gate insulating layer 123, a first interlayer insulating layer 124 covering the second gate conductive layer CPE and LB2 and the second gate insulating layer 123, a second semiconductor layer CH4, S4, and D4 disposed on the first interlayer insulating layer 124, a third gate insulating layer 125 covering the second semiconductor layer CH4, S4, and D4 and the first interlayer insulating layer 124, a third gate conductive layer G4 disposed on the third gate insulating layer 125, a second interlayer insulating layer 126 covering the third gate conductive layer G4 and the third gate insulating layer 125, a first source/drain conductive layer ANCE1, DCE, GCNE, and VIL disposed on the second interlayer insulating layer 126, a first planarization layer 127 covering the first source/drain conductive layer ANCE1, DCE, GCNE, and VIL and the second interlayer insulating layer 126, a second source/drain conductive layer ANCE2 and DL disposed on the first planarization layer 127, and a second planarization layer 128 covering the second source/drain conductive layer ANCE2 and DL and the first planarization layer 127.

The first transistor T1 may include a channel portion CH1, a source portion S1, and a drain portion D1 formed as the first semiconductor layer disposed on the buffer layer 121, and a gate electrode G1 disposed at the first gate conductive layer disposed on the first gate insulating layer 122 and overlapping the channel portion CH1 in a third direction DR3 (e.g., a thickness direction of the substrate 110).

The channel portion CH1 of the first transistor T1 may overlap the first light blocking layer LB1 disposed on the substrate 110 in the third direction DR3.

The second transistor T2 may include a channel portion CH2, a source portion S2, and a drain portion D2 formed as the first semiconductor layer disposed on the buffer layer 121, and a gate electrode G2 disposed at the first gate conductive layer disposed on the first gate insulating layer 122 and overlapping the channel portion CH2 in the third direction DR3.

The sixth transistor T6 may include a channel portion CH6, a source portion S6, and a drain portion D6 formed as the first semiconductor layer disposed on the buffer layer 121, and a gate electrode G6 disposed at the first gate conductive layer disposed on the first gate insulating layer 122 and overlapping the channel portion CH6 in the third direction DR3.

The source portion S2 of the second transistor T2 may be electrically connected to the data line DL through a data connection electrode DCE.

The data connection electrode DCE may be disposed at the first source/drain conductive layer disposed on the second interlayer insulating layer 126, and may be electrically connected to the source portion S2 of the second transistor T2 through a data connection auxiliary hole DCAH penetrating through the second interlayer insulating layer 126, the third gate insulating layer 125, the first interlayer insulating layer 124, the second gate insulating layer 123, and the first gate insulating layer 122.

The data line DL may be disposed at the second source/drain conductive layer disposed on the first planarization layer 127, and may be electrically connected to the data connection electrode DCE through a data connection hole DCH penetrating through the first planarization layer 127.

The drain portion D2 of the second transistor T2 may be connected to the source portion S1 of the first transistor T1.

The drain portion D1 of the first transistor T1 may be connected to the source portion S6 of the sixth transistor T6.

The drain portion D6 of the sixth transistor T6 may be electrically connected to an anode electrode 131 through a first anode connection electrode ANCE1 and a second anode connection electrode ANCE2.

The first anode connection electrode ANCE1 may be disposed at the first source/drain conductive layer disposed on the second interlayer insulating layer 126, and may be electrically connected to the drain portion D6 of the sixth transistor T6 through a first anode connection hole ANCH1 penetrating through the second interlayer insulating layer 126, the third gate insulating layer 125, the first interlayer insulating layer 124, the second gate insulating layer 123, and the first gate insulating layer 122.

The second anode connection electrode ANCE2 may be disposed at the second source/drain conductive layer disposed on the first planarization layer 127, and may be electrically connected to the first anode connection electrode ANCE1 through a second anode connection hole ANCH2 penetrating through the first planarization layer 127.

The anode electrode 131 may be disposed on the second planarization layer 128, and may be electrically connected to the second anode connection electrode ANCE2 through a third anode contact hole ANCH3 penetrating through the second planarization layer 128.

The first capacitor PC1 may be provided by an overlap area between a capacitor electrode CPE disposed at the second gate conductive layer disposed on the second gate insulating layer 123 and the gate electrode G1 of the first transistor T1.

The fourth transistor T4 may include a channel portion CH4, a source portion S4, and a drain portion D4 formed as the second semiconductor layer disposed on the first interlayer insulating layer 124, a gate electrode G4 disposed at the third gate conductive layer disposed on the third gate insulating layer 125, and a gate auxiliary electrode LB2 disposed at the second gate conductive layer disposed on the second gate insulating layer 123.

Each of the gate electrode G4 and the gate auxiliary electrode LB2 may overlap the channel portion CH4 of the fourth transistor T4 in the third direction DR3.

The source portion S4 of the fourth transistor T4 may be electrically connected to the first initialization voltage line VIL disposed on the second interlayer insulating layer 126 through an initialization voltage connection hole VICH penetrating through the second interlayer insulating layer 126 and the third gate insulating layer 125.

The drain portion D4 of the fourth transistor T4 may be electrically connected to the gate electrode G1 of the first transistor T1 through a gate connection electrode GCNE disposed at the first source/drain conductive layer disposed on the second interlayer insulating layer 126.

The gate connection electrode GCNE may be electrically connected to the drain portion D4 of the fourth transistor T4 through a first gate connection hole GCH1 penetrating through the second interlayer insulating layer 126 and the third gate insulating layer 125.

The gate connection electrode GCNE may be electrically connected to the gate electrode G1 of the first transistor T1 through a second gate connection hole GCH2 penetrating through the second interlayer insulating layer 126, the third gate insulating layer 125, the first interlayer insulating layer 124, and the second gate insulating layer 123.

In one or more embodiments, the third transistor T3 has a similar structure to the fourth transistor T4 and the fifth transistor T5, the seventh transistor T7, and the eighth transistor T8 each have a similar structure to the second transistor T2 and the sixth transistor T6, and an overlapping description will thus be omitted below.

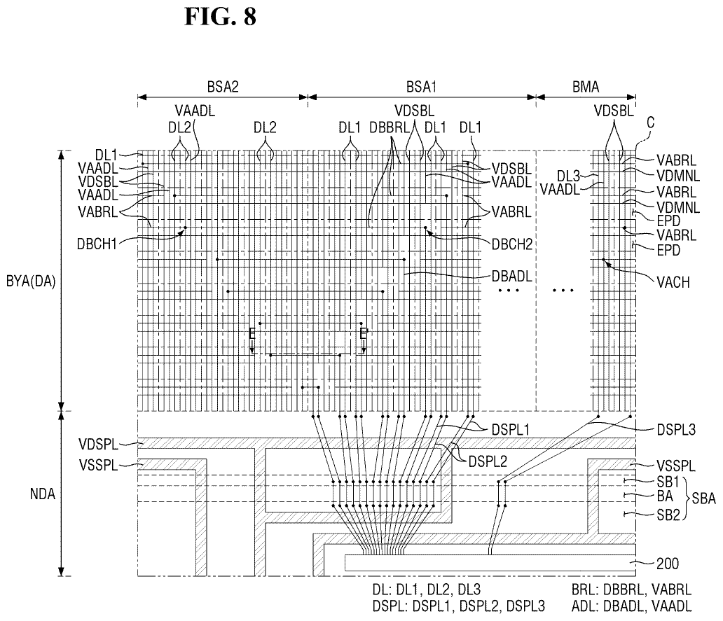

In one or more embodiments, the circuit layer 120 of the display device 100 may include bridge lines BRL (see FIG. 8) and additional lines ADL (see FIG. 8) in order to reduce a width of the non-display area NDA.

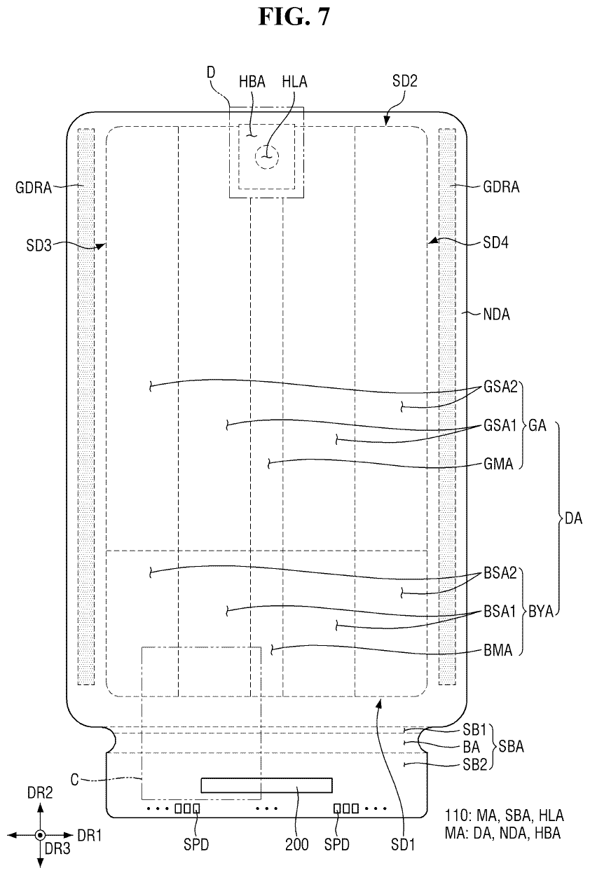

FIG. 7 is a plan view illustrating a substrate of FIG. 3.

Referring to FIG. 7, the substrate 110 of the display device 100 according to one or more embodiments includes a main area MA corresponding to a display surface and a sub-area SBA protruding from one side of the main area MA.

The main area MA includes a display area DA disposed at most of the center thereof and a non-display area NDA disposed at an edge or a periphery thereof and is around (e.g., surrounding) the display area DA.

An edge of the display area DA may include a first side SD1 that extends in the first direction DR1 and faces the sub-area SBA in the second direction DR2 and a second side SD2 that extends in the first direction DR1, opposes the first side SD1 in the second direction DR2, and is spaced farther from the sub-area SBA than the first side SD1 is.

In addition, the edge of the display area DA1 may further include a third side SD3 and a fourth side SD4 that extend in the second direction DR2 and oppose each other in the first direction DR1.

That is, the display area DA may have a rectangular shape including four sides SD1, SD2, SD3, and SD4.

The display area DA may include a bypass area BYA disposed on one side adjacent to the sub-area SBA in the second direction DR2 and a general area GA disposed in an area other than the bypass area BYA.

The bypass area BYA may include a bypass middle area BMA disposed in the middle, first bypass side areas BSA1 in contact with a side of the bypass middle area BMA, and second bypass side areas BSA2 disposed between the non-display area NDA and the first bypass side areas BSA1, in the first direction DR1.

The second bypass side area BSA2 may be disposed more adjacent to bent corners of the substrate 110 than the bypass middle area BMA and the first bypass side area BSA1 are.

One first bypass side area BSA1 and one second bypass side area BSA2 may be disposed on each of both sides of the bypass middle area BMA in the first direction DR1.

The general area GA may include a general middle area GMA connected to the bypass middle area BMA in the second direction DR2, first general side areas GSA1 connected to the first bypass side areas BSA1 in the second direction DR2, and second general side areas GSA2 connected to the second bypass side areas BSA2 in the second direction DR2.

The non-display area NDA may include a gate driving circuit area GDRA where a gate driving circuit is disposed.

The gate driving circuit area GDRA may be disposed in a portion of the non-display area NDA facing the third side SD3 and/or the fourth side SD4 of the display area DA.

The gate driving circuit in the gate driving circuit area GDRA may sequentially transfer gate signals to gate lines. Here, the gate lines may include the scan write line GWL (see FIG. 5) transferring the scan write signal GW (see FIG. 5), the scan initialization line GIL (see FIG. 5) transferring the scan initialization signal GI (see FIG. 5), the gate control line GCL (see FIG. 5) transferring the gate control signal GC (see FIG. 5), the bias control line GBL (see FIG. 5) transferring the bias control signal GB (see FIG. 5), and the emission control line ECL transferring the emission control signal EC (see FIG. 5).

The sub-area SBA may include a bending area BA transformed into a bent shape, a first sub-area SB1 disposed between one side of the bending area BA and the main area MA, and a second sub-area SB2 connected to the other side of the bending area BA.

When the bending area BA is transformed into the bent shape, the second sub-area SB2 is disposed below the substrate 110 and overlaps the main area MA in a third direction DR3.

The display driving circuit 200 may be disposed in the second sub-area SB2.

Signal pads SPD to which the circuit board 300 is connected may be disposed at an edge of one side of the second sub-area SB2.

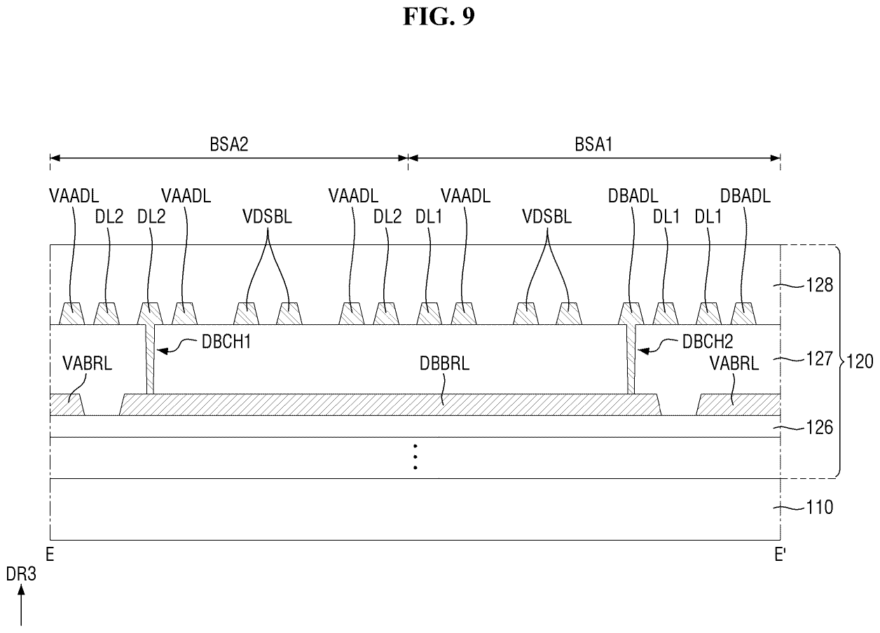

FIG. 8 is a layout diagram illustrating a portion C of FIG. 7. FIG. 9 is a cross-sectional view taken along the line E-E′ of FIG. 8.

Referring to FIG. 8, the circuit layer 120 of the display device 100 according to one or more embodiments may include emission pixel drivers EPD arranged along the first direction DR1 and the second direction DR2, data lines DL extending in the second direction DR2 and transferring data signals Vdata to the emission pixel drivers EPD, bridge lines BRL extending in the first direction DR1, and additional lines ADL extending in the second directions DR2 and neighboring the data lines DL.

The circuit layer 120 may further include first power sub-lines VDSBL extending in the second direction DR2 and transferring the first power ELVDD (see FIG. 5) and first power main lines VDMNL extending in the first direction DR1 and transferring the first power ELVDD (see FIG. 5). The first power main lines VDMNL and the first power sub-lines VDSBL are electrically connected to each other, and accordingly, the first power ELVDD may be supplied by lines having a mesh shape.

According to one or more embodiments, each of the emission pixel drivers EPD may overlap one data line DL, one additional line ADL paired with the one data line DL, and one first power sub-line VDSBL neighboring one of the one data line DL and the one additional line ADL.

In the first direction DR1, one additional line ADL may be disposed between one data line DL and one first power sub-line VDSBL.

That is, in the first direction DR1, two data lines DL facing each other may be disposed between additional lines ADL respectively paired with the two data lines DL.

In addition, in the first direction DR1, two first power sub-lines VDSBL facing each other may be disposed between additional lines ADL respectively neighboring the two first power sub-lines VDSBL.

According to one or more embodiments, each of the emission pixel drivers EPD may overlap one bridge line BRL and one first power main line VDMNL neighboring the one bridge line BRL.

That is, in the second direction DR2, the bridge lines BRL and the first power main lines VDMNL may be arranged alternately one by one.

According to one or more embodiments, the circuit layer 120 may further include data supply lines DSPL disposed in the non-display area NDA and electrically connected between the display driving circuit 200 and the data lines DL.

The data lines DL may include a first data line DL1 disposed in the first bypass side area BSA1 and a second data line DL2 disposed in the second bypass side area BSA2.

That is, the second data line DL2 is spaced farther from the sub-area SBA than the first data line DL1 is.

The bridge lines BRL may include a data bypass bridge line DBBRL electrically connected to the second data line DL2 of the second bypass side area BSA2.

The additional lines ADL may include a data bypass additional line DBADL disposed in the first bypass side area BSA1, neighboring the first data line DL1, and electrically connected to the data bypass bridge line DBBRL.

The data supply lines DSPL may include a first data supply line DSPL1 transferring a data signal of the first data line DL1 and a second data supply line DSPL2 transferring a data signal of the second data line DL2.

According to one or more embodiments, the data supply lines DSPL may extend to areas other than the second bypass side area BSA2 spaced relatively far from the sub-area SBA. That is, the data supply lines DSPL may extend to the first bypass side area BSA1 and the bypass middle area BMA.

Accordingly, the first data supply line DSPL1 may extend to the first data line DL1 of the first bypass side area BSA1, and may be directly electrically connected to the first data line DL1.

On the other hand, the second data supply line DSPL2 may extend to the data bypass additional line DBADL of the first bypass side area BSA1, and may be electrically connected to the second data line DL2 through the data bypass additional line DBADL and the data bypass bridge line DBBRL.

In this way, the second data supply line DSPL2 extend to the data bypass additional line DBADL of the first bypass side area BSA1 rather than to the second data line DL2 of the second bypass side area BSA2, and thus, an extension length of the second data supply line DSPL2 may be reduced. For this reason, a width of an area required for disposing the data supply lines DSPL may be reduced, and thus, a width of the non-display area NDA may be reduced.

In addition, the data supply lines DSPL are not arranged in the second bypass side area BSA2 adjacent to the bent corners of the substrate 110 in the non-display area NDA, and thus, the width of the non-display area NDA may be further reduced.

The data lines DL may further include a third data line DL3 disposed in the bypass middle area BMA.

In addition, the data supply lines DSPL may further include a third data supply line DSPL3 transferring a data signal of the third data line DL3.

The third data supply line DSPL3 may extend to the third data line DL3 of the bypass middle area BMA, and may be directly electrically connected to the third data line DL3.

The data bypass bridge line DBBRL may be disposed between the data bypass additional line DBADL and the second data line DL2.

The data bypass additional line DBADL may be disposed between the first side SD1 and the data bypass bridge line DBBRL.

In this way, the data bypass bridge line DBBRL and the data bypass additional line DBADL are limitedly disposed in the bypass area BYA, and accordingly, the presence or absence of the data bypass bridge line DBBRL and the data bypass additional line DBADL may be viewed.

In addition, both ends of the data bypass bridge line DBBRL and one end of the data bypass additional line DBADL are disposed in the display area DA, and thus, visibility of both ends of the data bypass bridge line DBBRL and one end of the data bypass additional line DBADL may be increased.

In order to prevent this, the bridge lines BRL may further include power auxiliary bridge lines VABRL as well as the data bypass bridge line DBBRL. In addition, the additional lines ADL may further include power auxiliary additional lines VAADL as well as the data bypass additional line DBADL.

One power auxiliary bridge line VABRL of the power auxiliary bridge lines VABRL may be disposed between one end of the data bypass bridge line DBBRL and the third side SD3, and the other power auxiliary bridge line VABRL of the power auxiliary bridge lines VABRL may be disposed between the other end of the data bypass bridge line DBBRL and the fourth side SD4.

One power auxiliary additional line VAADL of the power auxiliary additional lines VAADL may be disposed between one end of the data bypass additional line DBADL and the second side SD2.

Accordingly, some of the first data lines DL1 may neighbor the data bypass additional line DBADL, and the others of the first data lines DL1 may be adjacent to the power auxiliary additional line VAADL.

Because the data bypass additional line DBADL is disposed only in the first bypass side area BSA1, each of the second data line DL2 of the second bypass side area BSA2 and the third data line DL3 of the bypass middle area BMA may entirely neighbor the power auxiliary additional line VAADL.

The power auxiliary bridge lines VABRL and the power auxiliary additional lines VAADL may be electrically connected to each other through power auxiliary connection holes VACH.

The power auxiliary connection holes VACH may be disposed in an area other than the first bypass side area BSA1 and the second bypass side area BSA2 in the display area DA.

As illustrated in FIG. 8, the circuit layer 120 may further include a first power supply line VDSPL and a second power supply line VSSPL disposed in the non-display area NDA and respectively transferring the first power ELVDD and the second power ELVSS for driving the light emitting elements LE.

The second power supply line VSSPL may be formed to extend from one side of the first side SD1 of the edge of the display area DA to the other side of the first side SD1 via the third side SD3, the second side SD2, and the fourth side SD4.

The first power supply line VDSPL may be formed to face the first side SD1 of the edge of the display area DA.

Alternatively, the first power supply line VDSPL may be formed to extend from one side of the first side SD1 of the edge of the display area DA to the other side of the first side SD1 via the third side SD3, the second side SD2, and the fourth side SD4, like the second power supply line VSSPL, and may be disposed between the second power supply line VSSPL and the display area DA.

The first power supply line VDSPL and the second power supply line VSSPL may extend from the sub-area SBA.

The first power supply line VDSPL may be electrically connected to a first power pad for transferring the first power ELVDD from among the signal pads SPD disposed in the second sub-area SB2.

The second power supply line VSSPL may be electrically connected to a second power pad for transferring the second power ELVSS among the signal pads SPD disposed in the second sub-area SB2.

According to one or more embodiments, the power auxiliary bridge lines VABRL may be electrically connected to the second power supply line VSSPL.

The power auxiliary additional lines VAADL may be electrically connected to the power auxiliary bridge lines VABRL and the second power supply line VSSPL.

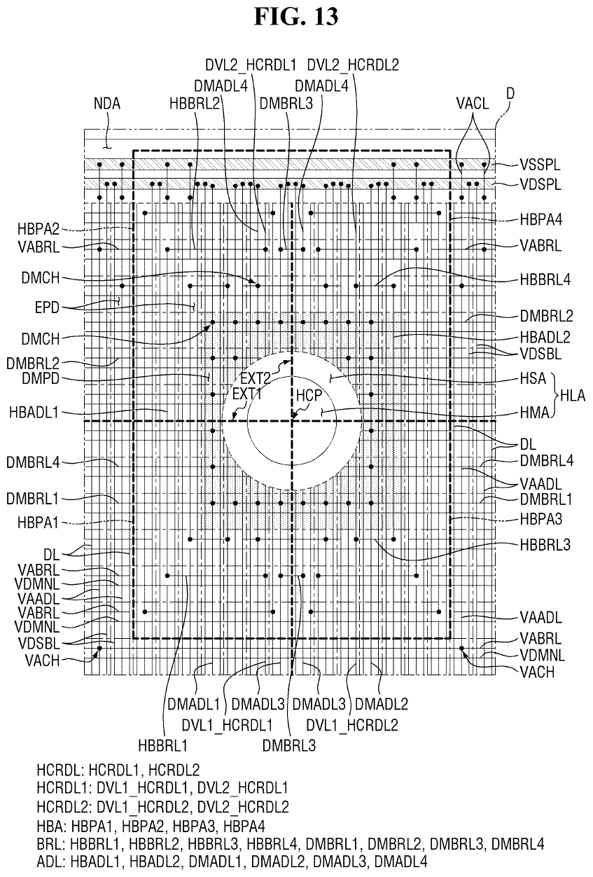

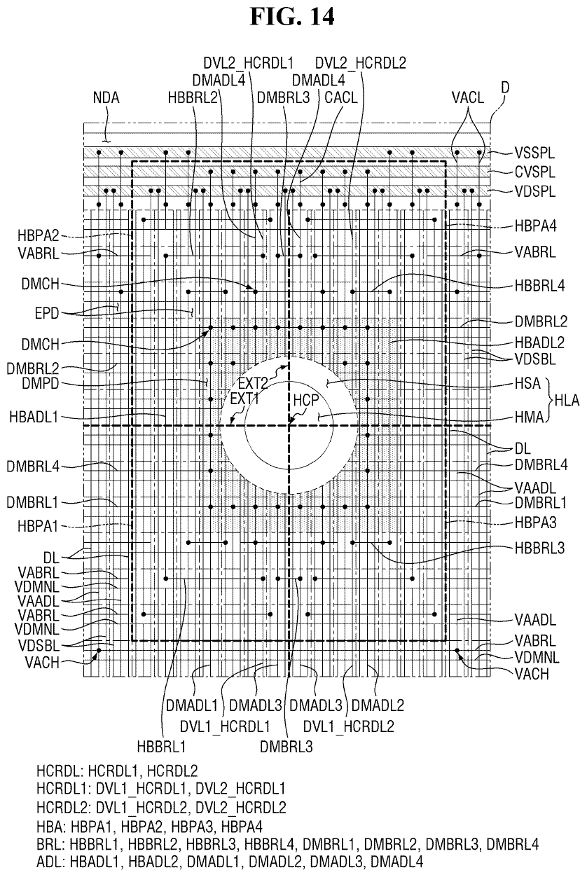

Alternatively, some of the power auxiliary bridge lines VABRL and some of the power auxiliary additional lines VAADL may be electrically connected to the second power supply line VSSPL, and the others of the power auxiliary bridge lines VABRL and the others of the power auxiliary additional line VAADL may be electrically connected to a constant voltage supply line CVSPL (see FIGS. 13 and 14).

The constant voltage supply line CVSPL (see FIGS. 13 and 14) may transfer one of the first initialization voltage VINT (see FIG. 5), the second initialization voltage VAINT (see FIG. 5), and the bias voltage VBS (see FIG. 5).

The first power main lines VDMNL and the first power sub-lines VDSBL may be electrically connected to the first power supply line VDSPL.

Referring to FIG. 9, the data lines DL, the additional lines ADL, and the first power sub-lines VDSBL may be disposed on at least one insulating layer (i.e., the first planarization layer 127) covering the bridge lines BRL and the first power main lines VDMNL.

That is, the bridge lines BRL and the first power main lines VDMNL may be disposed at the first source/drain conductive layer disposed on the second interlayer insulating layer 126.

The data lines DL, the additional lines ADL, and the first power sub-lines VDSBL may be disposed at the second source/drain conductive layer disposed on the first planarization layer 127.

The second data line DL2 may be electrically connected to the data bypass bridge line DBBRL through a first data bypass connection hole DBCH1 penetrating through the first planarization layer 127.

The data bypass additional line DBADL may be electrically connected to the data bypass bridge line DBBRL through a second data bypass connection hole DBCH2 penetrating through the first planarization layer 127.

Accordingly, the second data line DL2 may be electrically connected to the data bypass additional line DBADL through the data bypass bridge line DBBRL.

In addition, the data bypass additional line DBADL is electrically connected to the second data supply line DSPL2, and thus, the second data supply line DSPL2 may be electrically connected to the second data line DL2 through the data bypass additional line DBADL and the data bypass bridge line DBBRL.

As described above, according to one or more embodiments, the circuit layer 120 includes the data bypass additional line DBADL and the data bypass bridge line DBBRL disposed in the display area DA, and accordingly, the second data supply line DSPL2 may be electrically connected to the second data line DL2 even though it does not extend to the second data line DL2. Accordingly, an extension length of the data supply line DSPL2 may be reduced, and thus, the width of the non-display area NDA may be reduced.

As illustrated in FIG. 7, the substrate 110 of the display device 100 according to one or more embodiments may include a hole area HLA, and the main area MA of the substrate 110 may include a hole bypass area HBA disposed around the hole area HLA.

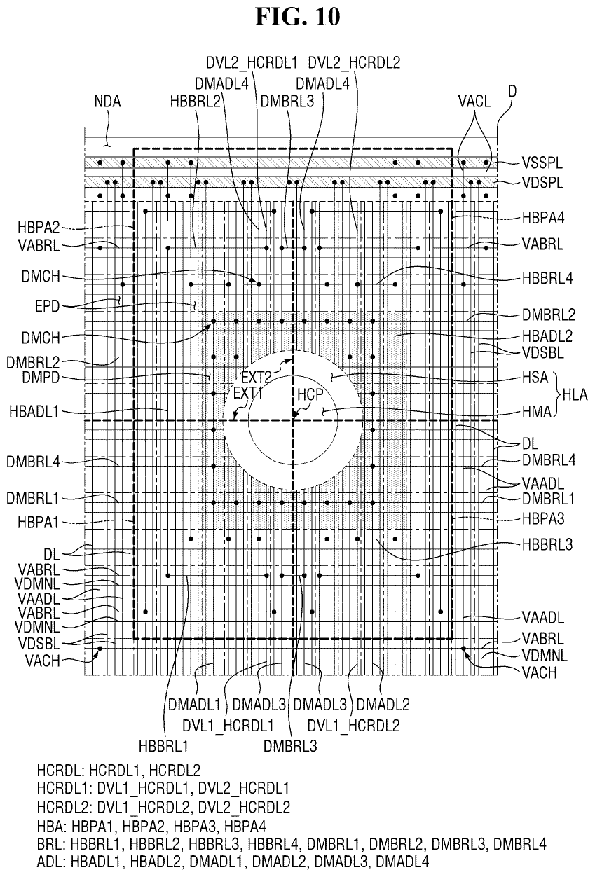

A light transmitting hole TRH (see FIG. 3) penetrating through the circuit layer 120, the element layer 130, and the sealing layer 140 is disposed in at least a portion of the middle of the hole area HLA, and accordingly, some hole crossing data lines HCRDL (see FIG. 10) crossing the hole area HLA from among the data lines DL of the circuit layer 120 are separated by the hole area HLA.

Accordingly, according to embodiments, separated portions of each of the hole crossing data lines HCRDL (see FIG. 10) may be electrically connected to each other using some bridge lines BRL and some additional lines ADL disposed in the hole bypass area HBA.

FIG. 10 is a layout diagram illustrating a portion D of FIG. 7 according to one or more embodiments.

Referring to FIG. 10, the substrate 110 of the display device 100 according to one or more embodiments may include the hole area HLA surrounded by the main area MA.

The hole area HLA may include a hole main area HMA disposed in the middle and a hole sub-area HSA disposed between the hole main area HMA and the hole bypass area HBA.

The light transmitting hole TRH penetrating through the circuit layer 120 and the element layer 130 may be disposed in the hole main area HMA. The light transmitting hole TRH may further penetrate through at least one of the substrate 110, the sealing layer 140, and the touch sensor layer 150.

A bonding structure of inorganic insulating materials for blocking permeation of oxygen or moisture by the light transmitting hole TRH may be disposed in the hole sub-area HSA.

The main area MA may include the display area DA where the emission areas EA are arranged, the non-display area NDA disposed around the display area DA, and the hole bypass area HBA disposed around the hole area HLA.

According to one or more embodiments, the circuit layer 120 may include the emission pixel drivers EPD arranged side by side along the first direction DR1 and the second direction DR2, the data lines DL extending in the second direction DR2, the bridge lines BRL extending in the first direction DR1, and the additional lines ADL extending in the second direction DR2 and neighboring the data lines DL.

According to one or more embodiments, the bridge lines BRL may include one or more first dummy bridge lines DMBRL1 facing the hole area HLA on one side in the second direction DR2 and one or more second dummy bridge lines DMBRL2 facing the hole area HLA on the other side in the second direction DR2.

Each of the one or more first dummy bridge lines DMBRL1 and the one or more second dummy bridge lines DMBRL2 may not cross the hole area HLA, and may be extend between the third side SD3 (see FIG. 7) and the fourth side SD4 (see FIG. 7).

The one or more first dummy bridge lines DMBRL1 may be one or more bridge lines BRL that do not cross the hole area HLA and are selected in the order adjacent to the hole area HLA on one side (lower side of FIG. 10) in the second direction DR2 from among the bridge lines BRL.

The one or more second dummy bridge lines DMBRL2 may be one or more bridge lines BRL that do not cross the hole area HLA and are selected in the order adjacent to the hole area HLA on the other side (upper side of FIG. 10) in the second direction DR2 from among the bridge lines BRL.

According to one or more embodiments, the additional lines ADL may include one or more first dummy additional lines DMADL1 facing the hole area HLA on one side in the first direction DR1.

The one or more first dummy additional lines DMADL1 may be one or more additional lines ADL that do not cross the hole area HLA and are selected in the order adjacent to the hole area HLA on one side (left side of FIG. 10) in the first direction DR1 from among the additional lines ADL.

According to one or more embodiments, the one or more first dummy additional lines DMADL1 may be electrically connected to the one or more first dummy bridge lines DMBRL1 and the one or more second dummy bridge lines DMBRL2.

In this way, the one or more first dummy bridge lines DMBRL1 and the one or more second dummy bridge lines DMBRL2 are electrically connected to each other through the one or more first dummy additional lines DMADL1, and accordingly, may have the same potential.

In addition, according to one or more embodiments, the additional lines ADL may include one or more second dummy additional lines DMADL2 facing the hole area HLA on the other side in the first direction DR1.

The one or more second dummy additional lines DMADL2 may be one or more additional lines ADL that do not cross the hole area HLA and are selected in the order adjacent to the hole area HLA on the other side (right side of FIG. 10) in the first direction DR1 from among the additional lines ADL.

The one or more second dummy additional lines DMADL2 may be electrically connected to the one or more first dummy bridge lines DMBRL1 and the one or more second dummy bridge lines DMBRL2.

In this way, the one or more first dummy bridge lines DMBRL1 and the one or more second dummy bridge lines DMBRL2, and the one or more first dummy additional lines DMADL1 and the one or more second dummy additional lines DMADL2 are electrically connected to each other, and accordingly, may have the same potential.

Therefore, a potential difference between the one or more first dummy bridge lines DMBRL1 and the one or more second dummy bridge lines DMBRL2, and the one or more first dummy additional lines DMADL1 and the one or more second dummy additional lines DMADL2 that are disposed most adjacent to the hole area HLA is eliminated, and thus, electrical influences of the one or more first dummy bridge lines DMBRL1 and the one or more second dummy bridge lines DMBRL2, and the one or more first dummy additional lines DMADL1 and the one or more second dummy additional lines DMADL2 may become similar to each other. Accordingly, a difference in image quality between emission areas EA adjacent to the hole area HLA may be reduced.

According to one or more embodiments, the hole bypass area HBA may include a first hole bypass partitioned area HBPA1 and a second hole bypass partitioned area HBPA2 that neighbor each other on the basis of a first hole central point extension line EXT1 crossing a central point HCP of the hole area HLA and extending in the first direction DR1, and a third hole bypass partitioned area HBPA3 and a fourth hole bypass partitioned area HBPA4 that respectively neighbor the first hole bypass partitioned area HBPA1 and the second hole bypass partitioned area HBPA2 on the basis of a second hole central point extension line EXT2 crossing the central point HCP of the hole area HLA and extending in the second direction DR2.

As an example, as illustrated in FIG. 10, the first hole bypass partitioned area HBPA1 may be disposed on the lower left side of the hole area HLA, the second hole bypass partitioned area HBPA2 may be disposed on the upper left side of the hole area HLA, the third hole bypass partitioned area HBPA3 may be disposed on the lower right side of the hole area HLA, and the fourth hole bypass partitioned area HBPA4 may be disposed on the upper right side of the hole area HLA.

The data lines DL may include hole crossing data lines HCRDL crossing the hole area HLA.

Each of the hole crossing data lines HCRDL is separated by the hole area HLA penetrating through the circuit layer 120, and may thus include a first divided line portion DVL1 disposed on one side of the hole area HLA and a second divided line portion DVL2 disposed on the other side of the hole area HLA.

That is, the first divided line portion DVL1: DVL1_HCRDL1 and DVL1_HCRDL2 of each of the hole crossing data lines HCRDL may be disposed between the first side SD1 (see FIG. 7) and the hole area HLA. In addition, the second divided line portion DVL2: DVL2_HCRDL1 and DVL2_HCRDL2 of each of the hole crossing data lines HCRDL may be disposed between the hole area HLA and the second side SD2.

In other words, the first divided line portion DVL1: DVL1_HCRDL1 and DVL1_HCRDL2 of each of the hole crossing data lines HCRDL may be disposed on one side of the second direction DR2 on the basis of the first hole central point extension line EXT1. In addition, the second divided line portion DVL2: DVL2_HCRDL1 and DVL2_HCRDL2 of each of the hole crossing data lines HCRDL may be disposed on the other side of the second direction DR2 on the basis of the first hole central point extension line EXT1.

The hole crossing data lines HCRDL may include a first hole crossing data line HCRDL1 (DVL1_HCRDL1 and DVL2_HCRDL1) facing the second hole central point extension line EXT2 on one side (e.g., the left side of FIG. 10) in the first direction DR1.

According to one or more embodiments, the bridge lines BRL may further include a first hole bypass bridge line HBBRL1 disposed in the first hole bypass partitioned area HBPA1 and electrically connected to the first divided line portion DVL1_HCRDL1 of the first hole crossing data line HCRDL1 and a second hole bypass bridge line HBBRL2 disposed in the second hole bypass partitioned area

HBPA2 and electrically connected to the second divided line portion DVL2_HCRDL1 of the first hole crossing data line HCRDL1.

The additional lines ADL may further include a first hole bypass additional line HBADL1 disposed in the first hole bypass partitioned area HBPA1 and the second hole bypass partitioned area HBPA2 and electrically connected between the first hole bypass bridge line HBBRL1 and the second hole bypass bridge line HBBRL2.

Accordingly, the first divided line portion DVL1_HCRDL1 of the first hole crossing data line HCRDL1 and the second divided line portion DVL2_HCRDL1 of the first hole crossing data line HCRDL1 may be electrically connected to each other while bypassing the hole area HLA through the first hole bypass bridge line HBBRL1, the first hole bypass additional line HBADL1, and the second hole bypass bridge line HBBRL2.

The one or more first dummy additional lines DMADL1 are most adjacent to the hole area HLA on one side in the first direction DR1, and may thus be disposed between the first hole bypass additional line HBADL1 and the hole area HLA in the first direction DR1.

In addition, the hole crossing data lines HCRDL may further include a second hole crossing data line HCRDL2 (DVL1_HCRDL2 and DVL2_HCRDL2) facing the second hole central point extension line EXT2 on the other side (e.g., the right side of FIG. 10) in the first direction DR1.

According to one or more embodiments, the bridge lines BRL may further include a third hole bypass bridge line HBBRL3 disposed in the third hole bypass partitioned area HBPA3 and electrically connected to the first divided line portion DVL1_HCRDL2 of the second hole crossing data line HCRDL2 and a fourth hole bypass bridge line HBBRL4 disposed in the fourth hole bypass partitioned area HBPA4 and electrically connected to the second divided line portion DVL2_HCRDL2 of the second hole crossing data line HCRDL2.

The additional lines ADL may further include a second hole bypass additional line HBADL2 disposed in the third hole bypass partitioned area HBPA3 and the fourth hole bypass partitioned area HBPA4 and electrically connected between the third hole bypass bridge line HBBRL3 and the fourth hole bypass bridge line HBBRL4.

Accordingly, the first divided line portion DVL1_HCRDL2 of the second hole crossing data line HCRDL2 and the second divided line portion DVL2_HCRDL2 of the second hole crossing data line HCRDL2 may be electrically connected to each other while bypassing the hole area HLA through the third hole bypass bridge line HBBRL3, the second hole bypass additional line HBADL2, and the fourth hole bypass bridge line HBBRL4.

The one or more second dummy additional lines DMADL2 are most adjacent to the hole area HLA on the other side in the first direction DR1, and may thus be disposed between the second hole bypass additional line HBADL2 and the hole area HLA in the first direction DR1.

According to one or more embodiments, the additional lines ADL may further include one or more third dummy additional lines DMADL3 and one or more fourth dummy additional lines DMADL4 that are disposed between the one or more first dummy additional lines DMADL1 and the one or more second dummy additional lines DMADL2 in the first direction DR1.

The one or more third dummy additional lines DMADL3 may be adjacent to one side of the hole area HLA in the second direction DR2 and may be disposed between the first side SD1 and the hole area HLA. That is, the one or more third dummy additional lines DMADL3 may be disposed in the first hole bypass partitioned area HBPA1 and the third hole bypass partitioned area HBPA3.

The one or more third dummy additional lines DMADL3 may be electrically connected to the one or more first dummy additional lines DMADL1 and the one or more second dummy additional lines DMADL2 through the one or more first dummy bridge lines DMBRL1.

The one or more fourth dummy additional lines DMADL4 may be adjacent to the other side of the hole area HLA in the second direction DR2 and may be disposed between the second side SD2 and the hole area HLA. That is, the one or more fourth dummy additional lines DMADL4 may be disposed in the second hole bypass partitioned area HBPA2 and the fourth hole bypass partitioned area HBPA4.

The one or more fourth dummy additional lines DMADL4 may be electrically connected to the one or more first dummy additional lines DMADL1 and the one or more second dummy additional lines DMADL2 through the one or more second dummy bridge lines DMBRL2.

According to one or more embodiments, the bridge lines BRL may further include two or more third dummy bridge lines DMBRL3 disposed between the first hole bypass bridge line HBBRL1 and the third hole bypass bridge line HBBRL3 and between the second hole bypass bridge line HBBRL2 and the fourth hole bypass bridge line HBBRL4 and one or more fourth dummy bridge lines DMBRL4 disposed between the one or more first dummy bridge lines DMBRL1 and the one or more second dummy bridge lines DMBRL2 in the second direction DR2.

The one or more fourth dummy bridge lines DMBRL4 may cross the hole area HLA. Accordingly, the one or more fourth dummy bridge lines DMBRL4 may be disposed between one side of the hole area HLA and the third side SD3 (see FIG. 7) and between the other side of the hole area HLA and the four side SD4 (see FIG. 7), in the first direction DR1.

Some third dummy bridge lines DMBRL3 disposed between the first hole bypass bridge line HBBRL1 and the third hole bypass bridge line HBBRL3 from among the two or more third dummy bridge lines DMBRL3 may be electrically connected to the one or more first dummy bridge lines DMBRL1 through the one or more third dummy additional lines DMADL3.

Some other third dummy bridge lines DMBRL3 disposed between the second hole bypass bridge line HBBRL2 and the fourth hole bypass bridge line HBBRL4 from among the two or more third dummy bridge lines DMBRL3 may be electrically connected to the one or more second dummy bridge lines DMBRL2 through the one or more fourth additional lines DMADL4.

Some fourth dummy bridge lines DMBRL4 disposed in the first hole bypass partitioned area HBPA1 and the second hole bypass partitioned area HBPA2 from among the one or more fourth dummy bridge lines DMBRL4 may be electrically connected to the one or more first dummy additional lines DMADL1.

Some other fourth dummy bridge lines DMBRL4 disposed in the third hole bypass partitioned area HBPA3 and the fourth hole bypass partitioned area HBPA4 from among the one or more fourth dummy bridge lines DMBRL4 may be electrically connected to the one or more second dummy additional lines DMADL2.

Accordingly, the two or more third dummy bridge lines DMBRL3, the one or more fourth dummy bridge lines DMBRL4, the one or more third dummy additional lines DMADL3, and the one or more fourth dummy additional lines DMADL4 may be electrically connected to the one or more first dummy bridge lines DMBRL1, the one or more second dummy bridge lines DMBRL2, the one or more first dummy additional lines DMADL1, and the one or more second dummy additional lines DMADL2.

In this way, the first, second, third and fourth dummy bridge lines DMBRL1, DMBRL2, DMBRL3, and DMBRL4 and the first, second, third, and fourth dummy additional lines DMADL1, DMADL2, DMADL3, and DMADL4 that are not electrically connected to the hole crossing data lines HCRDL from among the bridge lines BRL and the additional lines ADL disposed in the hole bypass area HBA have the same potential, and thus, electrical influences of the first, second, third and fourth dummy bridge lines DMBRL1, DMBRL2, DMBRL3, and DMBRL4 and the first, second, third, and fourth dummy additional lines DMADL1, DMADL2, DMADL3, and DMADL4 on the surroundings may become equal to each other. Accordingly, a difference in image quality between emission areas EA adjacent to the hole area HLA may be reduced.

According to one or more embodiments, the one or more first dummy bridge lines DMBRL1, the one or more second dummy bridge lines DMBRL2, the two or more third dummy bridge lines DMBRL3, and the one or more fourth dummy bridge lines DMBRL4 may be electrically connected to the one or more first dummy additional lines DMADL1, the one or more second dummy additional lines DMADL2, the one or more third dummy additional lines DMADL3, and the one or more fourth dummy additional lines DMADL4 through dummy connection holes DMCH.

According to one or more embodiments, the dummy connection holes DMCH may be arranged to be around (e.g., to surround) the hole area HLA so that the first, second, third, and fourth dummy bridge lines DMBRL1, DMBRL2, DMBRL3, and DMBRL4 and the first, second, third, and fourth dummy additional lines DMADL1, DMADL2, DMADL3 and DMADL4 are electrically connected to each other.

According to one or more embodiments, emission pixel drivers EPD may be arranged in the hole bypass area HBA like the display area DA.

The emission pixel drivers EPD in the hole bypass area HBA may include dummy emission pixel drivers DMPD in contact with the hole area HLA. The dummy emission pixel drivers DMPD may have the same structure as the emission pixel drivers EPD, but may not be used to supply the driving current.

As an example, the dummy emission pixel drivers DMPD may not be electrically connected to the data lines DL and/or may not be electrically connected to the light emitting elements LE.

In this way, even though some emission pixel drivers EPD adjacent to the hole area HLA are damaged in a process of disposing the light transmitting hole TRH (see FIG. 3) in the hole area HLA, it is possible to prevent image quality around the hole area HLA from being deteriorated.

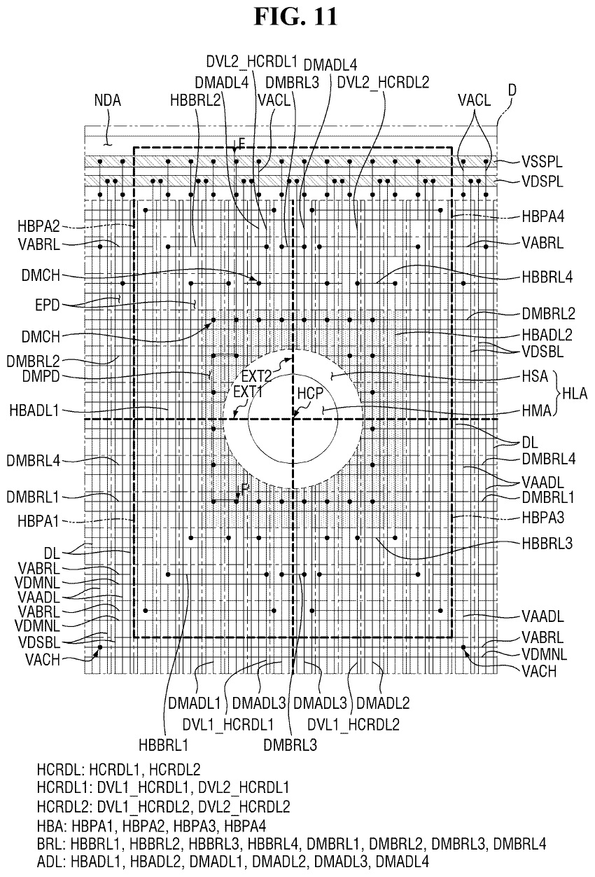

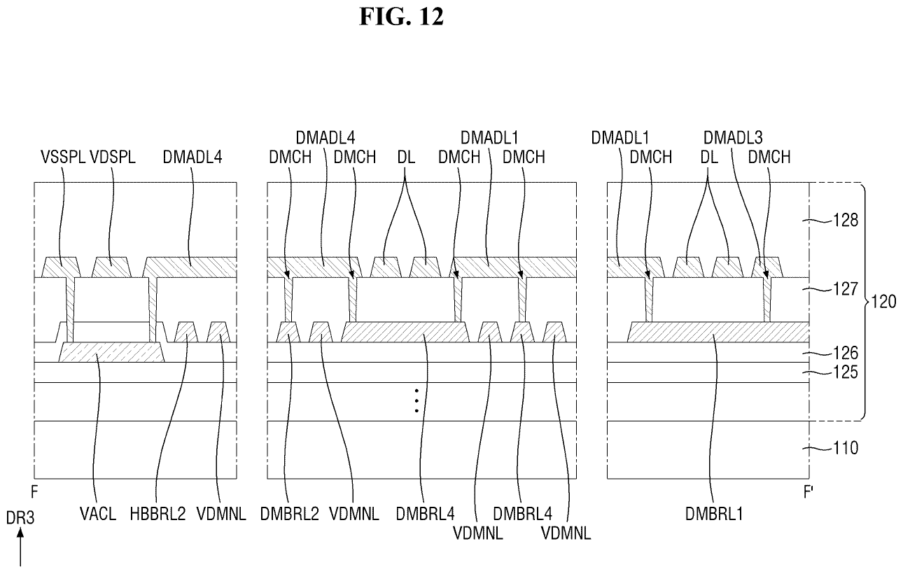

FIG. 11 is a layout diagram illustrating the portion D of FIG. 7 according to one or more embodiments. FIG. 12 is a cross-sectional view taken along the line F-F′ of FIG. 11.

A display device 100 according to one or more embodiments illustrated in FIG. 11 is substantially the same as the display device 100 according to embodiments illustrated in FIG. 10 except that one or more first dummy additional lines DMADL1 and one or more second dummy additional lines DMADL2 are electrically connected to a second power supply line VSSPL, and an overlapping description will thus be omitted below.

According to one or more embodiments, the circuit layer 120 may further include a first power supply line VDSPL and a second power supply line VSSPL disposed in the non-display area NDA and respectively transferring the first power ELVDD (see FIG. 5) and the second power ELVSS (see FIG. 5) for driving the light emitting elements LE (see FIG. 5).

A portion of the second power supply line VSSPL may extend in parallel with the second side SD2 relatively adjacent to the hole area HLA.

According to one or more embodiments of FIG. 11, the one or more first dummy additional lines DMADL1 and the one or more second dummy additional lines DMADL2 may be electrically connected to the second power supply line VSSPL.

In addition, according to an embodiment of FIG. 11, one or more fourth dummy additional lines DMADL4 may also be electrically connected to the second power supply line VSSPL.

As an example, when the first power supply line VDSPL is disposed between the display area DA and the second power supply line VSSPL and the first power supply line VDSPL and the second power supply line VSSPL are disposed at the same conductive layer, as illustrated in FIGS. 11 and 12, each of the one or more first dummy additional lines DMADL1, the one or more second dummy additional lines DMADL2, and the one or more fourth dummy additional lines DMADL4 may be electrically connected to the second power supply line VSSPL through a power auxiliary connection line VACL.

As illustrated in FIG. 12, the power auxiliary connection line VACL may be disposed at the third gate conductive layer disposed on the third gate insulating layer 125.

However, this is only an example, and the power auxiliary connection line VACL may be disposed at at least one of the first gate conductive layer, the second gate conductive layer, and the third gate conductive layer.

Each of the fourth dummy additional line DMADL4 and the second power supply line VSSPL may be electrically connected to the power auxiliary connection line VACL through a connection hole penetrating through the first planarization layer 127 and the second interlayer insulating layer 126.

The fourth dummy additional line DMADL4 may be electrically connected to each of the second dummy bridge line DMBRL2 and the fourth dummy bridge line DMBRL4 that cross the fourth dummy additional line DMADL4 through dummy connection holes DMCH penetrating through the first planarization layer 127.

The first dummy additional line DMADL1 may also be electrically connected to each of the first dummy bridge line DMBRL1 and the fourth dummy bridge line DMBRL4 that cross the first dummy additional line DMADL1 through dummy connection holes DMCH.

The third dummy additional line DMADL3 may be electrically connected to the first dummy additional line DMADL1 through the first dummy bridge line DMBRL1.

In one or more embodiments, when another line is not disposed between the display area DA and the second power supply line VSSPL unlike illustrated in FIGS. 11 and 12, the one or more first dummy additional lines DMADL1 and the one or more second dummy additional lines DMADL2 may extend to the non-display area NDA and may be directly electrically connected to the second power supply line VSSPL.

FIG. 13 is a layout diagram illustrating the portion D of FIG. 7 according to an embodiment.

A display device 100 according to one or more embodiments illustrated in FIG. 13 is substantially the same as the display device 100 according to one or more embodiments illustrated in FIG. 10 except that one or more first dummy additional lines DMADL1 and one or more second dummy additional lines DMADL2 are electrically connected to a first power supply line VDSPL, and an overlapping description will thus be omitted below.

According to one or more embodiments of FIG. 13, a portion of the first power supply line VDSPL may extend in parallel with the second side SD2 relatively adjacent to the hole area HLA.

According to one or more embodiments of FIG. 13, the one or more first dummy additional lines DMADL1 and the one or more second dummy additional lines DMADL2 may extend to the non-display area NDA and may be electrically connected to the first power supply line VDSPL.

In addition, according to one or more embodiments of FIG. 13, one or more fourth dummy additional lines DMADL4 may also extend to the non-display area NDA and be electrically connected to the first power supply line VDSPL.

FIG. 14 is a layout diagram illustrating the portion D of FIG. 7 according to an embodiment.

A display device 100 according to one or more embodiments illustrated in FIG. 14 is substantially the same as the display device 100 according to embodiments illustrated in FIG. 10 except that one or more first dummy additional lines DMADL1 and one or more second dummy additional lines DMADL2 are electrically connected to a constant voltage supply line CVSPL, and an overlapping description will thus be omitted below.

According to an embodiment of FIG. 14, the circuit layer 120 may further include a first power supply line VDSPL and a second power supply line VSSPL disposed in the non-display area NDA and respectively transferring the first power ELVDD (see FIG. 5) and the second power ELVSS (see FIG. 5) for driving the light emitting elements LE (see FIG. 5), and a constant voltage supply line CVSPL transferring a constant voltage having a different voltage level from the first power ELVDD and the second power ELVSS.

The constant voltage supply line CVSPL may transfer one of the first initialization voltage VINT (see FIG. 5), the second initialization voltage VAINT (see FIG. 5), and the bias voltage VBS (see FIG. 5).

However, this is only an example, and the constant voltage supply line CVSPL may also transfer a constant voltage having a different voltage level from the first initialization voltage VINT (see FIG. 5), the second initialization voltage VAINT (see FIG. 5), and the bias voltage VBS (see FIG. 5) as well as the first power ELVDD and the second power ELVSS.

As an example, when the first power supply line VDSPL is disposed between the display area DA and the constant voltage supply line CVSPL and the first power supply line VDSPL and the constant voltage supply line CVSPL are disposed at the same conductive layer, as illustrated in FIG. 14, each of the one or more first dummy additional lines DMADL1, the one or more second dummy additional lines DMADL2, and one or more fourth dummy additional lines DMADL4 may be electrically connected to the constant voltage supply line CVSPL through a constant voltage auxiliary connection line CACL.

Alternatively, when another line is not disposed between the display area DA and the constant voltage supply line CVSPL unlike illustrated in FIG. 14, the one or more first dummy additional lines DMADL1 and the one or more second dummy additional lines DMADL2 may extend to the non-display area NDA and may be directly electrically connected to the constant voltage supply line CVSPL.

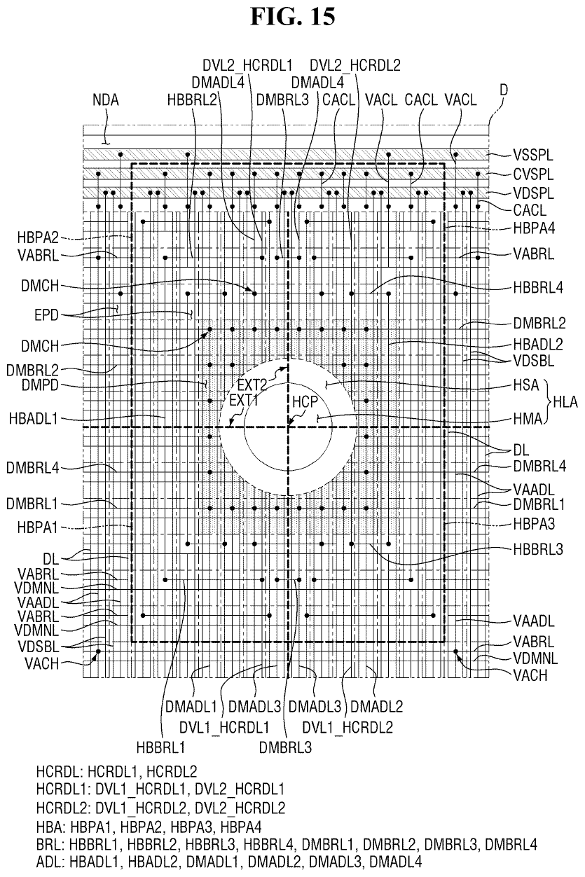

FIG. 15 is a layout diagram illustrating the portion D of FIG. 7 according to one or more embodiments.

A display device 100 according to one or more embodiments illustrated in FIG. 15 is substantially the same as the display device 100 according to one or more embodiments illustrated in FIG. 14 except that some of power auxiliary additional lines VAADL are electrically connected to the second power supply line VSSPL and the others of the power auxiliary additional lines VAADL are electrically connected to the constant voltage supply line CVSPL, and an overlapping description will thus be omitted below.

According to one or more embodiments of FIG. 15, some of the additional lines ADL disposed between one or more first dummy additional lines DMADL1 and the third side SD3 (see FIG. 7) may be electrically connected to the second power supply line VSSPL, and the others of the additional lines ADL disposed between the one or more first dummy additional lines DMADL1 and the third side SD3 (see FIG. 7) may be electrically connected to the constant voltage supply line CVSPL.

In addition, some of the additional lines ADL disposed between one or more second dummy additional lines DMADL2 and the fourth side SD4 (see FIG. 7) may be electrically connected to the second power supply line VSSPL, and the others of the additional lines ADL disposed between the one or more second dummy additional lines DMADL2 and the fourth side SD4 (see FIG. 7) may be electrically connected to the constant voltage supply line CVSPL.

In this way, the constant voltage of the constant voltage supply line CVSPL may be supplied to the display area DA through lines having a mesh shape by the others of the power auxiliary additional lines VAADL excluding some of the power auxiliary additional lines VAADL transferring the second power ELVSS.

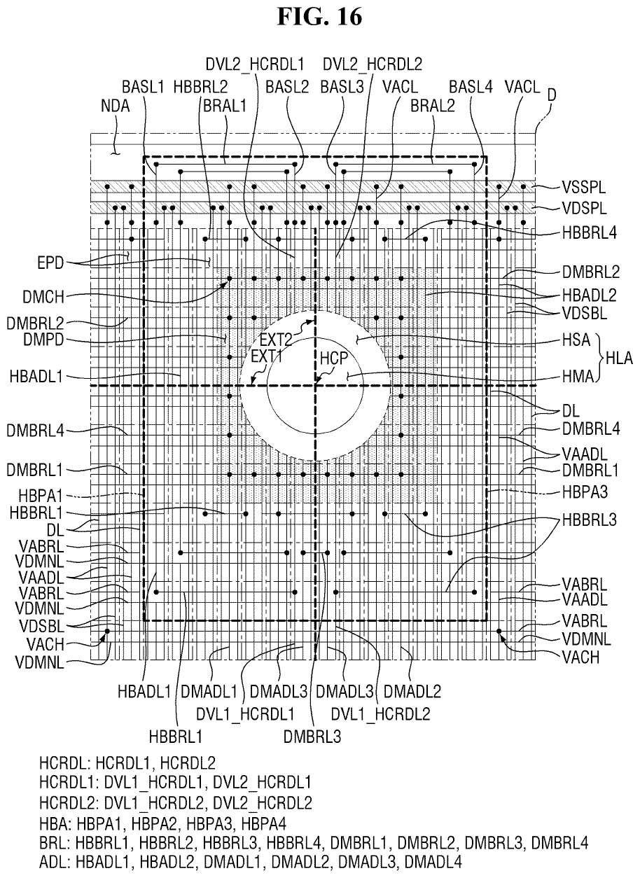

FIG. 16 is a layout diagram illustrating the portion D of FIG. 7 according to one or more embodiments.

A display device 100 according to one or more embodiments illustrated in FIG. 16 is substantially the same as the display device 100 according to one or more embodiments illustrated in FIG. 11 except that a portion of the hole bypass area HBA overlaps the display area DA and the other portion of the hole bypass area HBA overlaps the non-display area NDA, that a first bridge auxiliary line BRAL1 is electrically connected between the first hole bypass additional line HBADL1 and the second divided line portion DVL2_HCRDL1 of the first hole crossing data line HCRDL1 instead of at least one second hole bypass bridge line HBBRL2, and that a second bridge auxiliary line BRAL2 is electrically connected to the second hole bypass additional line HBADL2 and the second divided line portion DVL2_HCRDL2 of the second hole crossing data line HCRDL2 instead of at least one fourth hole bypass bridge line HBBRL4, and an overlapping description will thus be omitted below.

According to an embodiment of FIG. 16, the circuit layer 120 may further include a first bridge auxiliary line BRAL1 and a second bridge auxiliary line BRAL2 disposed in the non-display area NDA and extending in the first direction DR1.

The first auxiliary bridge line BRAL1 and the second auxiliary bridge line BRAL2 may be disposed between the second power supply line VSSPL and an edge of the substrate 110. However, this is only an example, and the first auxiliary bridge line BRAL1 and the second auxiliary bridge line BRAL2 may also be disposed adjacent to the second side SD2 of the display area DA.

According to one or more embodiments of FIG. 16, the circuit layer 120 may further include a first bypass auxiliary line BASL1 electrically connected between the first bridge auxiliary line BRAL1 and the first hole bypass additional line HBADL1, a second bypass auxiliary line BASL2 electrically connected between the first bridge auxiliary line BRAL1 and the second divided line portion DVL2_HCRDL1 of the first hole crossing data line HCRDL1, a third bypass auxiliary line BASL3 electrically connected between the second bridge auxiliary line BRAL2 and the second hole bypass additional line HBADL2, and a fourth bypass auxiliary line BASL4 electrically connected between the second bridge auxiliary line BRAL2 and the second divided line portion DVL2_HCRDL2 of the second hole crossing data line HCRDL2.

Each of the first bypass auxiliary line BASL1, the second bypass auxiliary line BASL2, the third bypass auxiliary line BASL3, and the fourth bypass auxiliary line BASL4 may extend in the second direction DR2.

As illustrated in FIG. 16, when the first power supply line VDSPL and the second power supply line VSSPL are sequentially arranged in parallel with the second side SD2, each of the first bypass auxiliary line BASL1, the second bypass auxiliary line BASL2, the third bypass auxiliary line BASL3, and the fourth bypass auxiliary line BASL4 may cross the first power supply line VDSPL and the second power supply line VSSPL.

The bridge lines BRL may be spaced from each other at suitable intervals (e.g., a predetermined intervals) so that they are arranged one by one at the respective emission pixel drivers EPD and DMPD, while the first bridge auxiliary line BRAL1 and the second bridge auxiliary line BRAL2 disposed in the non-display area NDA may be arranged at smaller intervals than the bridge lines BRL. Therefore, a width of the hole bypass area HBA may be reduced. In addition, the second hole bypass bridge line HBBRL2 and the fourth hole bypass bridge line HBBRL4 may be replaced with the first bridge auxiliary line BRAL1 and the second bridge auxiliary line BRAL2 in the non-display area NDA, and it is thus possible to prevent an interval between the second side SD2 and the hole area HLA from being increased due to the disposition of the second hole bypass bridge line HBBRL2 and the fourth hole bypass bridge line HBBRL4.

However, the effects, aspects and features of the present disclosure are not restricted to the one set forth herein. The above and other effects, aspects and features of the present disclosure will become more apparent to one of daily skill in the art to which the present disclosure pertains by referencing the claims.

What is claimed is:

1. A display device comprising:
a substrate;
a circuit layer on the substrate; and
an element layer on the circuit layer,
wherein the substrate includes a main area including a display area where emission areas are arranged and a non-display area around the display area, and a hole area, the main area being around the hole area,
the element layer comprises light emitting elements respectively in the emission areas, and
the circuit layer comprises:
emission pixel drivers arranged side by side along a first direction and a second direction and electrically connected to the light emitting elements, respectively;
data lines extending in the second direction and configured to supply data signals to the emission pixel drivers;
bridge lines extending in the first direction; and
additional lines extending in the second direction and neighboring the data lines,
the bridge lines comprise one or more first dummy bridge lines facing the hole area on one side in the second direction and one or more second dummy bridge lines facing the hole area on an other side in the second direction, and
the additional lines comprise one or more first dummy additional lines facing the hole area on the one side in the first direction and electrically connected to the one or more first dummy bridge lines and the one or more second dummy bridge lines.

2. The display device of claim 1, wherein the additional lines further comprise one or more second dummy additional lines facing the hole area on the other side in the first direction and electrically connected to the one or more first dummy bridge lines and the one or more second dummy bridge lines.

3. The display device of claim 2, wherein a light transmitting hole penetrating through the circuit layer and the element layer is in at least a portion of a middle of the hole area,
wherein the substrate further includes a sub-area protruding from one side of the main area,
wherein the main area further includes a hole bypass area around the hole area,
wherein the hole bypass area includes a first hole bypass partitioned area and a second hole bypass partitioned area that neighbor each other on the basis of a first hole central point extension line crossing a central point of the hole area and extending in the first direction, and a third hole bypass partitioned area and a fourth hole bypass partitioned area that respectively neighbor the first hole bypass partitioned area and the second hole bypass partitioned area on the basis of a second hole central point extension line crossing the central point of the hole area and extending in the second direction,
wherein an edge of the display area comprises a first side that extends in the first direction and faces the sub-area in the second direction and a second side that extends in the first direction, opposes the first side in the second direction, and is spaced farther from the sub-area than the first side is,
wherein the data lines comprise hole crossing data lines crossing the hole area,
wherein each of the hole crossing data lines comprises a first divided line portion between the first side and the hole area and a second divided line portion between the hole area and the second side,
wherein the hole crossing data lines comprise a first hole crossing data line facing the second hole central point extension line on one side in the first direction,
wherein the bridge lines further comprise a first hole bypass bridge line in the first hole bypass partitioned area and electrically connected to the first divided line portion of the first hole crossing data line and a second hole bypass bridge line in the second hole bypass partitioned area and electrically connected to the second divided line portion of the first hole crossing data line,
wherein the additional lines further comprise a first hole bypass additional line in the first hole bypass partitioned area and the second hole bypass partitioned area and electrically connected between the first hole bypass bridge line and the second hole bypass bridge line, and
wherein the one or more first dummy additional lines are between the first hole bypass additional line and the hole area in the first direction.

4. The display device of claim 3, wherein the hole crossing data lines further comprise a second hole crossing data line facing the second hole central point extension line on the other side in the first direction,
wherein the bridge lines further comprise a third hole bypass bridge line in the third hole bypass partitioned area and electrically connected to the first divided line portion of the second hole crossing data line and a fourth hole bypass bridge line in the fourth hole bypass partitioned area and electrically connected to the second divided line portion of the second hole crossing data line,
wherein the additional lines further comprise a second hole bypass additional line in the third hole bypass partitioned area and the fourth hole bypass partitioned area and electrically connected between the third hole bypass bridge line and the fourth hole bypass bridge line, and
wherein the one or more second dummy additional lines are between the hole area and the second hole bypass additional line in the first direction.

5. The display device of claim 4, wherein the additional lines further comprise:
one or more third dummy additional lines between the first side and the hole area in the second direction and between the one or more first dummy additional lines and the one or more second dummy additional lines in the first direction; and
one or more fourth dummy additional lines between the hole area and the second side in the second direction and between the one or more first dummy additional lines and the one or more second dummy additional lines in the first direction,
wherein the one or more third dummy additional lines are electrically connected to the one or more first dummy additional lines and the one or more second dummy additional lines through the one or more first dummy bridge lines, and
wherein the one or more fourth dummy additional lines are electrically connected to the one or more first dummy additional lines and the one or more second dummy additional lines through the one or more second dummy bridge lines.

6. The display device of claim 5, wherein the bridge lines further comprise:
two or more third dummy bridge lines between the first hole bypass bridge line and the third hole bypass bridge line and between the second hole bypass bridge line and the fourth hole bypass bridge line; and
one or more fourth dummy bridge lines between the one or more first dummy bridge lines and the one or more second dummy bridge lines in the second direction and crossing the hole area,
wherein the two or more third dummy bridge lines are electrically connected to the one or more first dummy bridge lines or the one or more second dummy bridge lines through the one or more third dummy additional lines and the one or more fourth dummy additional lines, and
wherein the one or more fourth dummy bridge lines are electrically connected to the one or more first dummy additional lines or the one or more second dummy additional lines.

7. The display device of claim 6, wherein a portion of the second hole bypass partitioned area overlaps the display area, and an other portion of the second hole bypass partitioned area overlaps the non-display area, and
wherein the circuit layer further comprises a first bridge auxiliary line in the non-display area, extending in the first direction, and electrically connected between the first hole bypass additional line and the second divided line portion of the first hole crossing data line.

8. The display device of claim 7, wherein a portion of the fourth hole bypass partitioned area overlaps the display area, and an other portion of the fourth hole bypass partitioned area overlaps the non-display area, and
the circuit layer further comprises a second bridge auxiliary line in the non-display area, extending in the first direction, and electrically connected between the second hole bypass additional line and the second divided line portion of the second hole crossing data line.

9. The display device of claim 6, wherein the circuit layer further comprises a first power supply line and a second power supply line in the non-display area and respectively configured to supply first power and second power to drive the light emitting elements,
wherein a portion of the second power supply line extends in parallel with the second side, and
wherein the one or more first dummy additional lines and the one or more second dummy additional lines are electrically connected to the second power supply line.

10. The display device of claim 6, wherein the circuit layer further comprises a first power supply line and a second power supply line in the non-display area and respectively configured to supply first power and second power to drive the light emitting elements,
wherein a portion of the first power supply line extends in parallel with the second side, and
wherein the one or more first dummy additional lines and the one or more second dummy additional lines are electrically connected to the first power supply line.

11. The display device of claim 6, wherein the circuit layer further comprises:
a first power supply line and a second power supply line in the non-display area and respectively configured to supply first power and second power to drive the light emitting elements; and
a constant voltage supply line configured to supply a constant voltage having a different voltage level from the first power and the second power in the non-display area,
wherein a portion of the constant voltage supply line extends in parallel with the second side, and
wherein the one or more first dummy additional lines and the one or more second dummy additional lines are electrically connected to the constant voltage supply line.

12. The display device of claim 11, wherein one of the light emitting elements is electrically connected between one of the emission pixel drivers and the second power,
wherein the emission pixel driver comprises:
a first transistor configured to generate a driving current for driving the light emitting element;
a second transistor electrically connected between one of the data lines and a first electrode of the first transistor;
a third transistor electrically connected between a gate electrode of the first transistor and a second electrode of the first transistor;
a fourth transistor electrically connected between a first initialization voltage line configured to supply a first initialization voltage and the gate electrode of the first transistor;
a fifth transistor electrically connected between a first power line configured to supply the first power and the first electrode of the first transistor;
a sixth transistor electrically connected between the second electrode of the first transistor and the light emitting element;
a seventh transistor electrically connected between a second initialization voltage line configured to supply a second initialization voltage and the light emitting element; and
an eighth transistor electrically connected between a bias voltage line configured to supply a bias voltage and the first electrode of the first transistor, and
wherein the constant voltage supply line is configured to supply one of the first initialization voltage, the second initialization voltage, and the bias voltage.

13. The display device of claim 6, wherein the data lines further comprise a first data line and a second data line that is spaced farther from the sub-area than the first data line is,
wherein the bridge lines further comprise a data bypass bridge line electrically connected to the second data line, and
wherein the additional lines further comprise a data bypass additional line neighboring the first data line and electrically connected to the data bypass bridge line.

14. The display device of claim 13, wherein the circuit layer further comprises data supply lines electrically connected between a display driving circuit in the sub-area and the data lines,
a first data supply line configured to supply a data signal of the first data line from among the data supply lines extends to the first data line and is directly electrically connected to the first data line, and
a second data supply line configured to supply a data signal of the second data line from among the data supply lines extends to the data bypass additional line and is electrically connected to the second data line through the data bypass additional line and the data bypass bridge line.

15. The display device of claim 13, wherein the edge of the display area further comprises a third side and a fourth side that extend in the second direction and oppose each other in the first direction,
wherein the data bypass bridge line is spaced from the third side and the fourth side,
wherein the bridge lines further comprise power auxiliary bridge lines between one end of the data bypass bridge line and the third side and between other end of the data bypass bridge line and the fourth side, and
wherein the additional lines further comprise a power auxiliary additional line between one end of the data bypass additional line and the second side.

16. A display device comprising:
a substrate;
a circuit layer on the substrate; and
an element layer on the circuit layer,
wherein the substrate comprises a main area including a display area where emission areas are arranged and a non-display area around the display area, a hole area, and a sub-area protruding from one side of the main area, the main area being around the hole area,
the element layer comprises light emitting elements respectively located in the emission areas,
the circuit layer comprises:
emission pixel drivers arranged side by side along a first direction and a second direction and electrically connected to the light emitting elements, respectively;
data lines extending in the second direction and configured to supply data signals to the emission pixel drivers;
bridge lines extending in the first direction; and
additional lines extending in the second direction and neighboring the data lines,
the main area further includes a hole bypass area around the hole area,
the data lines comprise hole crossing data lines crossing the hole area,
each of the hole crossing data lines comprises a first divided line portion on one side in the second direction and a second divided line portion on the other side in the second direction, on the basis of a first hole central point extension line crossing a central point of the hole area and extending in the first direction,
the hole crossing data lines comprise a first hole crossing data line on one side in the first direction and a second hole crossing data line on the other side in the first direction, on the basis of a second hole central point extension line crossing the central point of the hole area and extending in the second direction,
the bridge lines comprise:
a first hole bypass bridge line electrically connected to the first divided line portion of a first hole bridge data line;
a second hole bypass bridge line electrically connected to the second divided line portion of the first hole bridge data line;
a third hole bypass bridge line electrically connected to the first divided line portion of a second hole bridge data line;
a fourth hole bypass bridge line electrically connected to the second divided line portion of the second hole bridge data line;
one or more first dummy bridge lines facing the hole area on one side in the second direction; and
one or more second dummy bridge lines facing the hole area on the other side in the second direction,
the additional lines comprise:
a first hole bypass additional line electrically connected between the first hole bypass bridge line and the second hole bypass bridge line;
a second hole bypass additional line electrically connected between the third hole bypass bridge line and the fourth hole bypass bridge line;
one or more first dummy additional lines facing the hole area on one side in the first direction and electrically connected to the first dummy bridge line and the second dummy bridge line; and
one or more second dummy additional lines facing the hole area on the other side in the first direction and electrically connected to the first dummy bridge line and the second dummy bridge line, and
the one or more first dummy bridge lines, the one or more second dummy bridge lines, the one or more first dummy additional lines, and the one or more second dummy additional lines are electrically connected to each other.

17. The display device of claim 16, wherein the bridge lines further comprise:
two or more third dummy bridge lines between the first hole bypass bridge line and the third hole bypass bridge line and between the second hole bypass bridge line and the fourth hole bypass bridge line; and
one or more fourth dummy bridge lines between the one or more first dummy bridge lines and the one or more second dummy bridge lines in the second direction and crossing the hole area,
wherein the additional lines further comprise:
one or more third dummy additional lines adjacent to one side of the hole area in the second direction and between the one or more first dummy additional lines and the one or more second dummy additional lines in the first direction; and
one or more fourth dummy additional lines adjacent to the other side of the hole area in the second direction and between the one or more first dummy additional lines and the one or more second dummy additional lines in the first direction, and
the two or more third dummy bridge lines, the one or more fourth dummy bridge lines, the one or more third dummy additional lines, and the one or more fourth dummy additional lines are electrically connected to the one or more first dummy bridge lines, the one or more second dummy bridge lines, the one or more first dummy additional lines, and the one or more second dummy additional lines.

18. The display device of claim 17, wherein the circuit layer further comprises a first power supply line and a second power supply line in the non-display area and respectively configured to supply first power and second power to drive the light emitting elements, and
wherein the one or more first dummy additional lines and the one or more second dummy additional lines are electrically connected to one of the first power supply line and the second power supply line.

19. The display device of claim 17, wherein the circuit layer further comprises:
a first initialization voltage line configured to supply a first initialization voltage to the emission pixel drivers;
a second initialization voltage line configured to supply a second initialization voltage to the emission pixel drivers;
a bias voltage line transferring a bias voltage to the emission pixel drivers; and
a constant voltage supply line in the non-display area,
wherein the constant voltage supply line is configured to supply one of the first initialization voltage, the second initialization voltage, and the bias voltage, and
wherein the one or more first dummy additional lines and the one or more second dummy additional lines are electrically connected to the constant voltage supply line.

20. The display device of claim 17, wherein a portion of the hole bypass area overlaps the display area, and an other portion of the hole bypass area overlaps the non-display area, and
wherein the circuit layer further comprises:
a first bridge auxiliary line in the non-display area, extending in the first direction, and electrically connected between the first hole bypass additional line and the second divided line portion of the first hole crossing data line; and
a second bridge auxiliary line in the non-display area, extending in the first direction, and electrically connected between the second hole bypass additional line and the second divided line portion of the second hole crossing data line.
